(19) United States
(12) Patent Application Publication
(10) Pub. No.: US 2024/0014081 A1
(43) Pub. Date: Jan. 11, 2024

(54) SEMICONDUCTOR STRUCTURE FOR INSPECTION

(71) Applicant: ROHM CO., LTD., Kyoto-shi (JP)

(72) Inventors: Toshiro TAKAO, Kyoto-shi (JP); Katsuhisa NAGAO, Kyoto-shi (JP); Yoshiro ENOKIDA, Kyoto-shi (JP)

(73) Assignee: ROHM CO., LTD., Kyoto-shi (JP)

(21) Appl. No.: 18/474,315

(22) Filed: Sep. 26, 2023

Related U.S. Application Data
(63) Continuation of application No. PCT/JP2022/007253, filed on Feb. 22, 2022.

(30) Foreign Application Priority Data
Mar. 26, 2021 (JP) 2021-053878

(51) Int. Cl. H01L 21/66; G01R 31/26; H01L 21/67

(52) U.S. Cl. CPC H01L 22/32; G01R 31/2601; G01R 31/2644; H01L 22/14; H01L 21/67288

(57) ABSTRACT

A semiconductor structure for inspection includes a semiconductor plate having a first main surface on one side and a second main surface on the other side, an inspection region provided in the first main surface, a main surface electrode having a first hardness and covering the first main surface in the inspection region, and a protective electrode having a second hardness which exceeds the first hardness, covering the main surface electrode in the inspection region, and forming a current path between the second main surface and the protective electrode via the semiconductor plate.

### CROSS-REFERENCE TO RELATED APPLICATIONS

The present application is a continuation of International Application No. PCT/JP2022/007253, filed Feb. 22, 2022, which corresponds to Japanese Patent Application No. 2021-053878 filed on Mar. 26, 2021 with the Japan Patent Office, and the entire disclosure of each application is incorporated herein by reference.

### BACKGROUND

### 1. Field of the Disclosure

The present disclosure relates to a semiconductor structure for inspection.

### 2. Description of the Related Art

Japanese Patent Application Publication No. 2016-139646 discloses a semiconductor device for inspection used for inspection of a semiconductor evaluation device. The semiconductor evaluation device includes a chuck stage, a probe, and an evaluation portion. The chuck stage has a mounting surface on which a semiconductor wafer is arranged at the time of evaluation. The probe is arranged so as to be capable of coming into contact with the semiconductor wafer arranged on the mounting surface. The evaluation portion is electrically connected to the chuck stage and the probe, and evaluates electrical characteristics relating to the semiconductor wafer.

The semiconductor device for inspection is an inspection tool that inspects the mounting surface of the chuck stage before evaluating the semiconductor wafer. The semiconductor device for inspection includes a silicon wafer and a plurality of resistors. The silicon wafer is connected to the mounting surface. The plurality of resistors are provided to be separated from each other on the silicon wafer, and connected to the probe. The mounting surface is inspected based on contact resistance of the chuck stage and the silicon wafer.

### BRIEF DESCRIPTION OF THE DRAWINGS

FIG. 1 is a schematic view showing a first example embodiment of a semiconductor evaluation device.

FIG. 2 is a plan view showing a semiconductor structure for inspection according to a first embodiment.

FIG. 3 is a sectional view taken along line III-III shown in FIG. 2.

FIG. 4 is a flowchart for describing a manufacturing method of a semiconductor device by using the semiconductor evaluation device shown in FIG. 1 and the semiconductor structure for inspection shown in FIG. 2.

FIG. 5A is a schematic view for describing the flowchart shown in FIG. 4.

FIG. 5B is a schematic view for describing a step subsequent to that of FIG. 5A.

FIG. 5C is a schematic view for describing a step subsequent to that of FIG. 5B.

FIG. 5D is a schematic view for describing a step subsequent to that of FIG. 5C.

FIG. 5E is a schematic view for describing a step subsequent to that of FIG. 5D.

FIG. 5F is a schematic view for describing a step subsequent to that of FIG. 5E.

FIG. 6 is a graph showing the reliability of the semiconductor structure for inspection shown in FIG. 2.

FIG. 7 is a plan view showing a semiconductor structure for inspection according to a second embodiment.

FIG. 8 is a sectional view taken along line VIII-VIII shown in FIG. 7.

FIG. 9 is a sectional view in which major parts of a functional device shown in FIG. 7 are enlarged.

FIG. 10 is a schematic view showing a second example embodiment of the semiconductor evaluation device shown in FIG. 1.

FIG. 11 is a schematic view showing a third example embodiment of the semiconductor evaluation device shown in FIG. 1.

### DETAILED DESCRIPTION OF THE PREFERRED EMBODIMENTS

Hereinafter, embodiments will be described in detail with reference to the attached drawings. The attached drawings are not strictly drawn and are schematic views in which a scale, etc., do not necessarily match. The same reference signs are given to the corresponding structures between the attached drawings, and duplicated descriptions will be omitted or simplified. To the structures whose descriptions are omitted or simplified, the descriptions made before the omission or the simplification are applied.

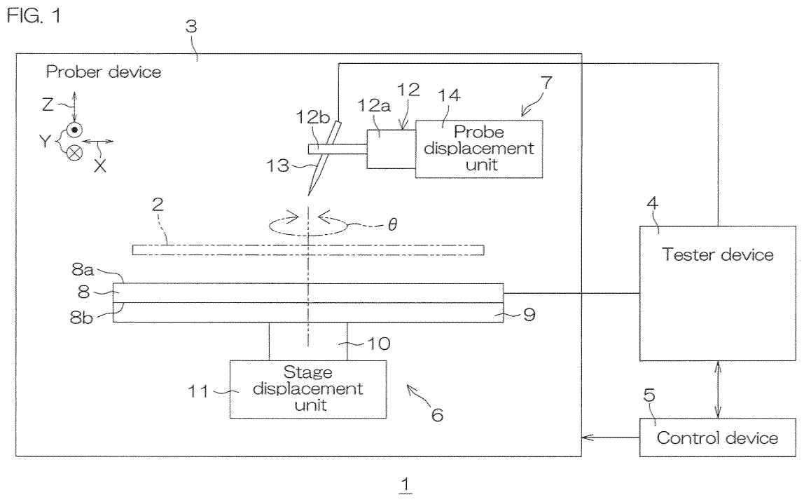

FIG. 1 is a schematic view showing a first example embodiment of a semiconductor evaluation device 1. The semiconductor evaluation device 1 is a device for measuring electrical characteristics of a semiconductor structure 2 (see a double-chain line portion) serving as an object to be measured. The semiconductor evaluation device 1 includes a prober device 3, a tester device 4, and a control device 5. The prober device 3 includes a stage unit 6 and a probe unit 7.

The stage unit 6 includes a chuck stage 8, an insulating plate 9, a support portion 10, and a stage displacement unit 11. In this embodiment, the chuck stage 8 is formed in a disc shape. The chuck stage 8 has a conductive mounting surface 8a on which the semiconductor structure 2 is to be arranged, and a non-mounting surface 8b on the opposite side to the mounting surface 8a. In this embodiment, the chuck stage 8 is made of a conductive plate, and has conductivity over the entire region in the thickness direction including the mounting surface 8a and the non-mounting surface 8b. The chuck stage 8 may be configured to absorb and support the semiconductor structure 2 on the mounting surface 8a.

The insulating plate 9 is made of an insulating plate-shaped member, and arranged on the non-mounting surface 8b side. The support portion 10 supports the chuck stage 8 via the insulating plate 9. The stage displacement unit 11 is connected to the support portion 10, and configured to displace the chuck stage 8 via the support portion 10. The stage displacement unit 11 may be configured to displace the chuck stage 8 in the first direction X along the mounting surface 8a, in the second direction Y orthogonal to the first direction X along the mounting surface 8a, in the vertical direction Z with respect to the mounting surface 8a, and in the turning direction ⊖ passing through a central portion of the mounting surface 8a and having the vertical direction Z as the turning axis in response to an electric signal from the outside.

In this embodiment, the probe unit 7 is of a manipulator type, and includes a manipulator 12, a conductive probe needle 13, and a probe displacement unit 14. In this embodiment, the manipulator 12 includes a body portion 12a and an arm portion 12b. The mode of the body portion 12a is arbitrary and not limited to a particular mode. The arm portion 12b is connected to the body portion 12a, and formed in an arm shape (such as an axis shape, a columnar shape, a tubular shape, and a plate shape) so as to extend from the body portion 12a along the mounting surface 8a.

The shape of the arm portion 12b is arbitrary. The arm portion 12b may extend in parallel to the mounting surface 8a or may extend to be inclined obliquely with respect to the mounting surface 8a. Also, the arm portion 12b may be formed in a curved shape having a part inclined from the body portion 12a toward the mounting surface 8a, and a part curved from the inclined portion so as to extend along the mounting surface 8a.

The probe needle 13 is formed by a needle-shape member made of a metal material, and has a sharp needle tip to be abutted with the semiconductor structure 2. The probe needle 13 may be made of at least one of tungsten, a tungsten alloy, a palladium alloy, and a gold alloy. The probe needle 13 is supported by the manipulator 12. Specifically, the probe needle 13 is detachably attached to the arm portion 12b. The probe needle 13 is attached to the arm portion 12b in an inclined posture or an upstanding posture with respect to the mounting surface 8a. As a matter of course, the probe needle 13 may arrange a coaxial probe with the arm portion 12b.

The probe displacement unit 14 is connected to the manipulator 12 and displaces a relative position of the probe needle 13 with respect to the mounting surface 8a (semiconductor structure 2) via the manipulator 12. The probe displacement unit 14 may be configured to displace the probe needle 13 in at least one of the first direction X, the second direction Y, and the vertical direction Z in response to the electric signal from the outside. The probe displacement unit 14 may be configured to move the probe needle 13 between an inspection position opposing the mounting surface 8a and a retreat position placed outside of the mounting surface 8a.

The number of the probe unit 7 is adjusted in accordance with the number of electrodes (abutment points) of an inspection object portion of the semiconductor structure 2. In a case where the inspection object portion of the semiconductor structure 2 has a plurality of electrodes allocated in an array shape, a plurality of probe units 7 corresponding to the plurality of electrodes are provided. In a case where the inspection object portion of the semiconductor structure 2 has a single electrode, one or a plurality of probe units 7 corresponding to the single electrode are provided.

The tester device 4 is electrically connected to the mounting surface 8a and the probe needle 13, and gives a predetermined electric signal between the mounting surface 8a and the probe needle 13. The tester device 4 measures the electrical characteristics of the semiconductor structure 2 based on an energization result between the mounting surface 8a and the probe needle 13. Also, the tester device 4 inspects a state of the mounting surface 8a based on the energization result between the mounting surface 8a and the probe needle 13. Specifically, the state of the mounting surface 8a is indirectly inspected by using an inspection tool for the mounting surface 8a.

The tester device 4 is configured to give an arbitrary voltage or an arbitrary electric current between the mounting surface 8a and the probe needle 13. In this embodiment, the tester device 4 is configured to apply an arbitrary electric current between the mounting surface 8a and the probe needle 13. The tester device 4 may give an electric current from the probe needle 13 side or may give an electric current from the chuck stage 8 side in accordance with an electric specification of the semiconductor structure 2. In this embodiment, the tester device 4 gives an electric current from the probe needle 13 toward the chuck stage 8. The electric current may be not less than 1 mA and not more than 200 A.

The tester device 4 is preferably configured to acquire one of or both of a voltage value and a resistance value between the mounting surface 8a and the probe needle 13. In a case where the tester device 4 measures a voltage value, the voltage value may be not more than 10 V. In a case where the tester device 4 measures a resistance value, the resistance value may be not more than 200 mΩ. The resistance value may be a contact resistance value between the mounting surface 8a and the semiconductor structure 2.

The control device 5 is connected to the prober device 3 and the tester device 4, and controls the prober device 3 and the tester device 4. The control device 5 may be connected to the prober device 3 via a cable or may be connected to the prober device 3 via a communication interface such as a wireless LAN and a wired LAN. The control device 5 may be connected to the tester device 4 via a cable or may be connected to the tester device 4 via a communication interface such as a wireless LAN and a wired LAN.

The control device 5 may include a computer having a main control unit, an input unit, an output unit, a memory unit, and a display unit. The main control unit may include a CPU, a RAM, and a ROM. The input unit may include a keyboard, a mouse, etc. The output unit may include a printer, etc.

The memory unit may include a storage medium in which processing recipes, etc., are stored. The storage medium may be a hard disk, an optical disc, a flash memory, etc. The display unit may display information on the semiconductor structure 2, information on the prober device 3, information on the tester device 4, information on the processing recipes, etc., in response to functions of the main control unit, etc.

The control device 5 reads the processing recipes, creates control signals that control the prober device 3 and the tester device 4 by predetermined processing actions based on the processing recipes, and outputs the control signals to the prober device 3 and the tester device 4. The control device 5 is configured to acquire a measurement result from the tester device 4 and display the measurement result on the display unit.

The control device 5 may be configured to display the measurement result in the tester device 4 on the display unit by means of a map (such as a wafer map or a map of the mounting surface 8a). The control device 5 executes a right/wrong judgment of the electrical characteristics of the semiconductor structure 2 based on the measurement result in the tester device 4. Also, the control device 5 executes a right/wrong judgment of the mounting surface 8a based on the measurement result in the tester device 4.

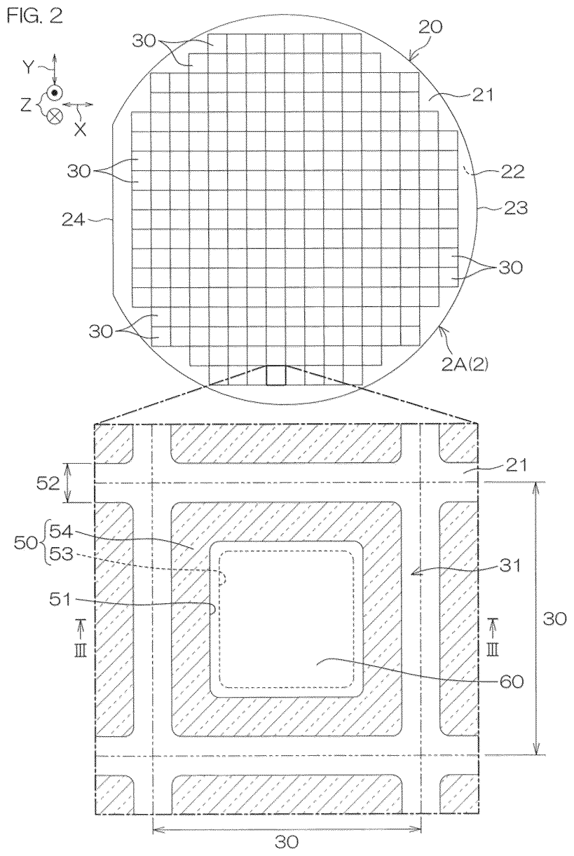

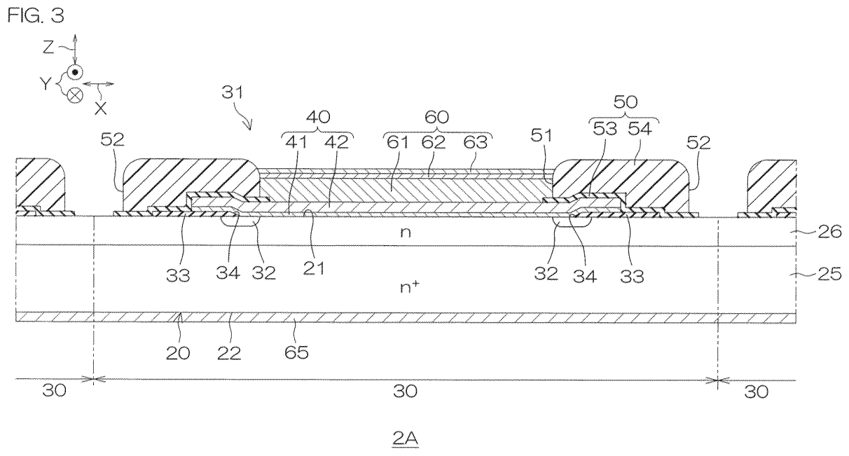

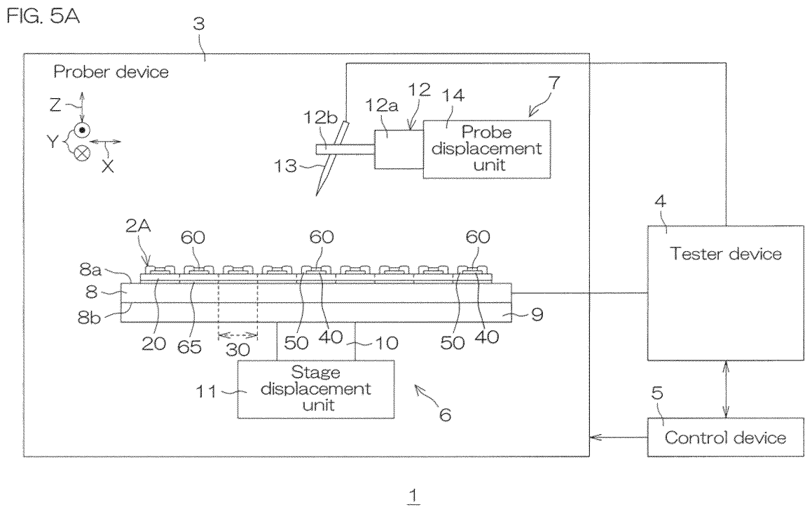

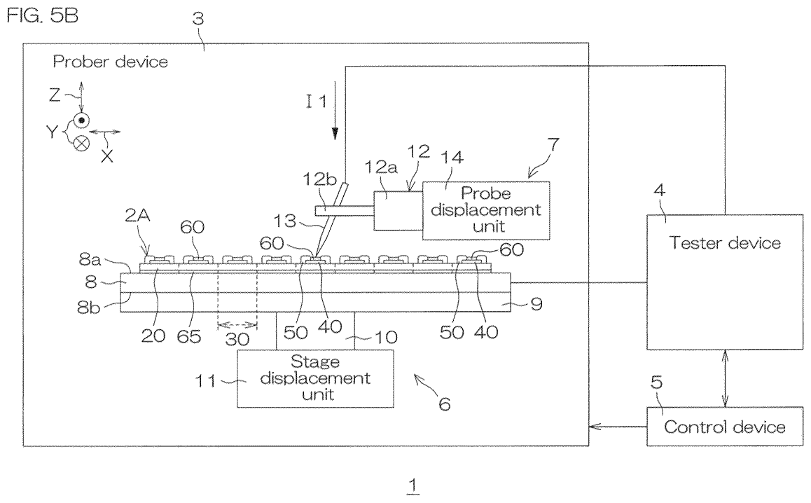

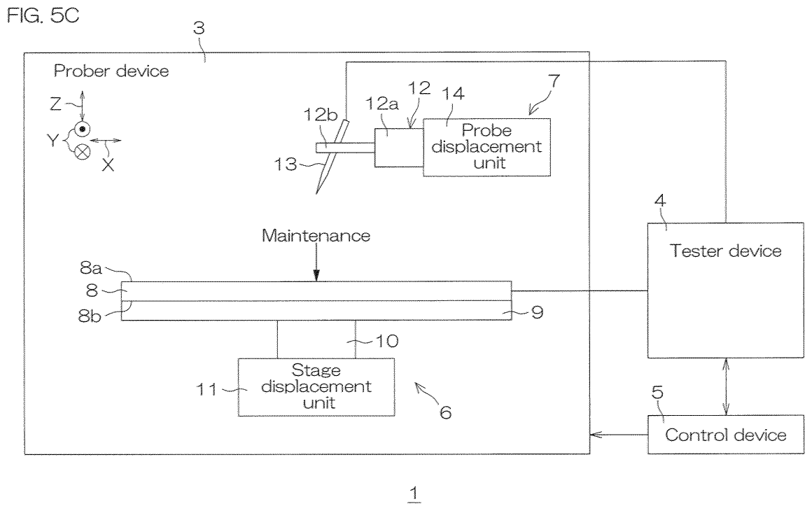

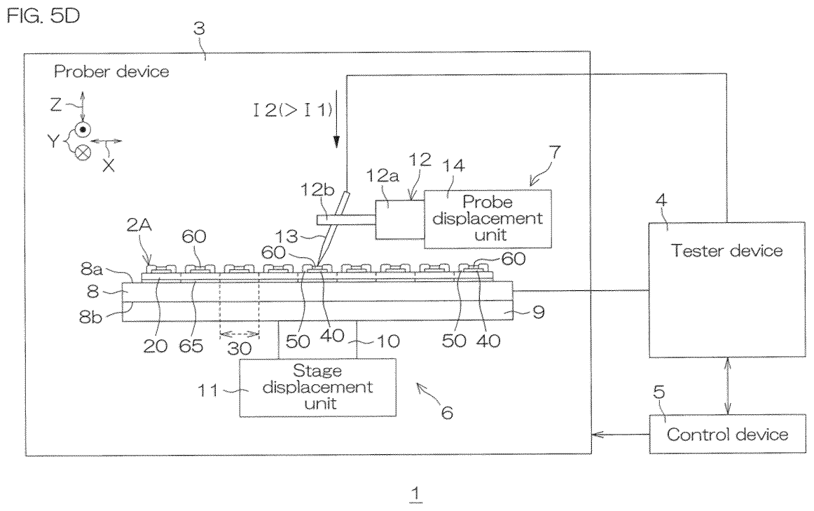

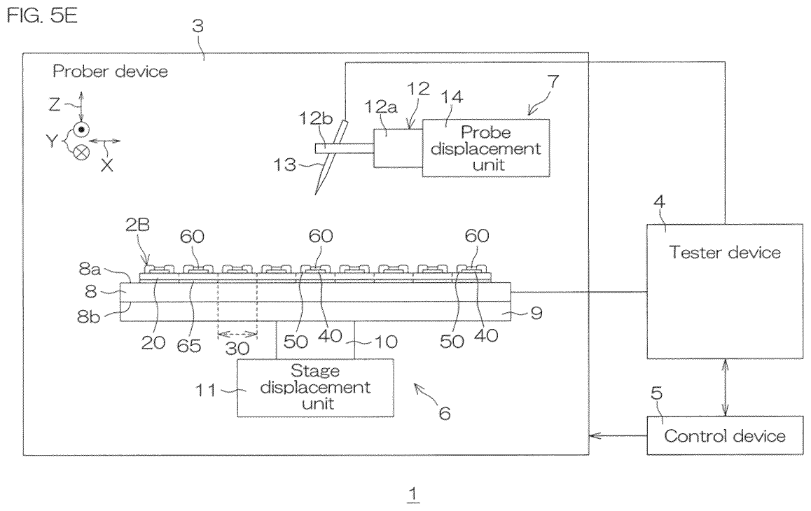

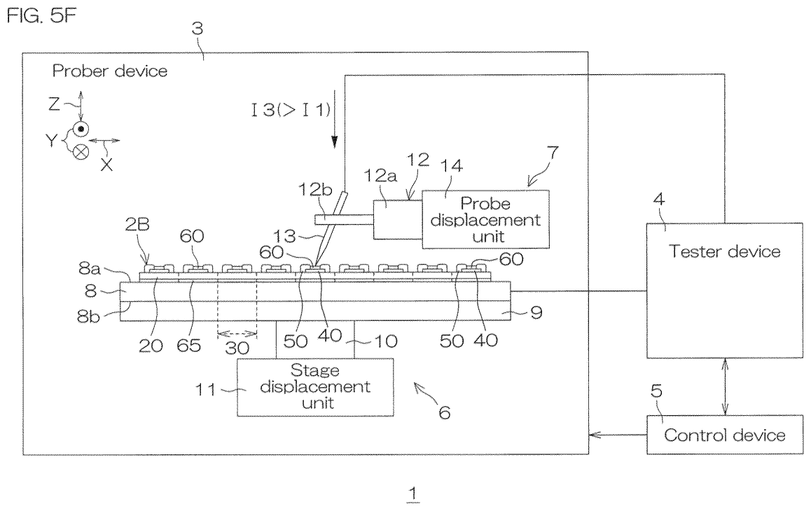

FIG. 2 is a plan view showing a semiconductor structure 2A for inspection according to a first embodiment. FIG. 3 is a sectional view taken along line III-III shown in FIG. 2. The semiconductor structure 2A for inspection is a tool to be used for inspection of the mounting surface 8a before evaluation of a semiconductor structure 2B for manufacture (see FIG. 5E to be described later) at a stage prior to processing into semiconductor devices, and is different from a use of the semiconductor structure 2B for manufacture in a point that the semiconductor structure 2A for inspection is not processed into semiconductor devices. The semiconductor structure 2A for inspection configures a chuck stage inspection device that inspects the mounting surface 8a of the chuck stage 8 together with the semiconductor evaluation device 1. Both the semiconductor structure 2A for inspection and the semiconductor structure 2B for manufacture are examples of the semiconductor structure 2.

With reference to FIGS. 2 and 3, the semiconductor structure 2A for inspection includes a disc-shaped semiconductor wafer 20 serving as an example of a semiconductor plate. The semiconductor wafer 20 preferably does not include an Si (silicon) single crystal. In this embodiment, the semiconductor wafer 20 is made of a wide-bandgap semiconductor wafer including a wide-bandgap semiconductor. The wide-bandgap semiconductor is a semiconductor having a bandgap higher than that of Si.

In this embodiment, the semiconductor wafer 20 is made of an SiC semiconductor wafer including a hexagonal SiC (silicon carbide) single crystal which serves as an example of the wide-bandgap semiconductor. FIG. 2 shows the example that the first direction X is the m-axis direction of the SiC single crystal, and the second direction Y is the a-axis direction of the SiC single crystal. The hexagonal SiC single crystal has a plurality of polytypes including a 2H (hexagonal)-SiC single crystal, a 4H-SiC single crystal, a 6H-SiC single crystal, etc. Although this embodiment shows the example that the semiconductor structure 2A for inspection is made of a 4H-SiC single crystal, other polytypes are not excluded.

The semiconductor wafer 20 has a first main surface 21 on one side, a second main surface 22 on the other side, and a side surface 23 that connects the first main surface 21 and the second main surface 22. The first main surface 21 and the second main surface 22 face a c-plane of the SiC single crystal. Preferably, the first main surface 21 faces a silicon plane of the SiC single crystal and the second main surface 22 faces a carbon plane of the SiC single crystal.

The first main surface 21 and the second main surface 22 may have an off angle inclined by a predetermined angle in the predetermined off direction with respect to the c-plane. That is, the c-axis of the SiC single crystal may be inclined by the off angle with respect to the vertical direction Z. The off direction is preferably the a-axis direction (direction of [11-20]) of the SiC single crystal. The off angle may exceed 0° and may be not more than 10°. The off angle is preferably not more than 5°. The off angle is particularly preferably not less than 2° and not more than 4.5°.

The semiconductor wafer 20 has a mark 24 indicating the crystal orientation of the SiC single crystal on the side surface 23. In this embodiment, the mark 24 includes an orientation flat cut out in a linear shape in a plan view seen from the vertical direction Z (hereinafter, simply referred to as “a plan view”). In this embodiment, the mark 24 extends in the a-axis direction of the SiC single crystal. The mark 24 does not necessarily extend in the a-axis direction but may extend in the m-axis direction.

As a matter of course, the semiconductor structure 2A for inspection may include the mark 24 extending in the a-axis direction and a mark 24 extending in the m-axis direction. Also, in place of or in addition to the orientation flat, the mark 24 may have an orientation notch recessed toward a central portion of the first main surface 21 along the a-axis direction or the m-axis direction in a plan view.

The semiconductor wafer 20 may have a diameter of not less than 50 mm and not more than 300 mm (that is, not less than 2 inches and not more than 12 inches) in a plan view. The diameter of the semiconductor wafer 20 is defined by a length of a chord passing through the center of the semiconductor structure 2A for inspection outside of the mark 24. The semiconductor wafer 20 may have a thickness of not less than 100 μm and not more than 1,000 μm.

The semiconductor structure 2A for inspection includes an n-type (first conductivity type) first semiconductor region 25 formed in a region on the second main surface 22 side in the semiconductor wafer 20. The first semiconductor region 25 is formed in a layer shape extending along the second main surface 22, and exposed from the second main surface 22 and the side surface 23. The first semiconductor region 25 may have a thickness of not less than 50 μm and not more than 995 μm.

The semiconductor structure 2A for inspection includes an n-type second semiconductor region 26 formed in a region on the first main surface 21 side in the semiconductor wafer 20. The second semiconductor region 26 has an n-type impurity concentration lower than the first semiconductor region 25, and is electrically connected to the first semiconductor region 25 in the semiconductor wafer 20. The second semiconductor region 26 is formed in a layer shape extending along the first main surface 21, and exposed from the first main surface 21 and the side surface 23. The second semiconductor region 26 has a thickness less than the thickness of the first semiconductor region 25 in the vertical direction Z. The thickness of the second semiconductor region 26 may be not less than 5 μm and not more than 50 μm. The thickness of the second semiconductor region 26 is preferably not more than 30 μm.

In this embodiment, the first semiconductor region 25 is formed by a semiconductor substrate (specifically, an SiC semiconductor substrate), and forms the second main surface 22 and part of the side surface 23. In this embodiment, the second semiconductor region 26 is formed by an epitaxial layer (specifically, an SiC epitaxial layer), and forms the first main surface 21 and part of the side surface 23. That is, the semiconductor wafer 20 has a laminated structure including the semiconductor substrate and the epitaxial layer.

The semiconductor structure 2A for inspection includes a plurality of inspection regions 30 provided in the first main surface 21. The plurality of inspection regions 30 are respectively set in a square shape in a plan view. In this embodiment, the plurality of inspection regions 30 are allocated in a matrix along the first direction X and the second direction Y in a plan view. The plurality of inspection regions 30 regulate the minimum unit of an area of measurement with respect to the mounting surface 8a of the chuck stage 8. That is, a ratio of the plurality of inspection regions 30 in the first main surface 21 regulates a resolution capability with respect to the mounting surface 8a. By reducing a plane area of the inspection regions 30 and increasing the number of the inspection regions 30, the resolution capability with respect to the mounting surface 8a is improved, and accuracy of detecting foreign substances adhering to the mounting surface 8a is improved.

Each of the inspection regions 30 preferably has a plane area of not less than 0.1 mm×0.1 mm. The plane area of each of the inspection regions 30 is preferably not more than 25 mm×25 mm. The plurality of inspection regions 30 preferably occupy not less than 70% and less than 100% of an area of the first main surface 21. Further, in a state where the semiconductor structure 2A for inspection is arranged on the mounting surface 8a, the plurality of inspection regions 30 preferably occupy not less than 70% and less than 100% of an area where the semiconductor structure 2A for inspection and the mounting surface 8a are in contact with each other.

The number of inspection regions 30 may be not less than 10 and not more than 3,000. In a case where a semiconductor wafer 20 (SiC wafer) having a diameter of not more than 100 mm (not more than 4 inches) is applied, the number of the inspection regions 30 may be not less than 10 and not more than 100. In a case where a semiconductor wafer 20 (SiC wafer) having a diameter of not less than 100 mm (not less than 4 inches) is applied, the number of the inspection regions 30 may be not less than 100 and not more than 3,000.

The semiconductor structure 2A for inspection further includes a plurality of functional devices 31 each of which is respectively formed in each of the inspection regions 30 on the first main surface 21. Each of the functional devices 31 is formed by utilizing part of the second semiconductor region 26 at an interval inward from a peripheral edge of each of the inspection regions 30. All the functional devices 31 are preferably formed by the same devices having equal electrical characteristics. Each of the functional devices 31 may include at least one of a switching device, a rectification device, and a passive device.

The switching device may include at least one of a metal insulator semiconductor field effect transistor (MISFET), a bipolar junction transistor (BJT), an insulated gate bipolar junction transistor (IGBT), and a junction field effect transistor (JFET). The rectification device may include at least one of a pn junction diode, a pin junction diode, a Zener diode, a Schottky barrier diode (SBD), and a fast recovery diode (FRD). The passive device may include at least one of a resistor, a capacitor, and an inductor.

Each of the functional devices 31 may include a circuit network (for example, an integrated circuit such as an LSI) in which at least two of the switching device, the rectification device, and the passive device are combined. In this embodiment, each of the functional devices 31 includes the SBD. Since the plurality of inspection regions 30 (functional devices 31) have the same structure, a structure of a single inspection region 30 (functional device 31) will be described below.

The semiconductor structure 2A for inspection includes a p-type (second conductivity type) guard region 32 formed in a surface layer portion of the first main surface 21 in the inspection region 30. The guard region 32 is formed in a surface layer portion of the second semiconductor region 26 at an interval inward from the peripheral edge of the inspection region 30. The guard region 32 is formed in a ring shape (in this embodiment, a square ring shape) surrounding an inner side portion of the inspection region 30 in a plan view. Thereby, the guard region 32 is formed as a guard ring region. The guard region 32 has an inner edge portion on the inner side portion side of the inspection region 30, and an outer edge portion on the peripheral edge side of the inspection region 30.

The semiconductor structure 2A for inspection includes a main surface insulating film 33 covering the main surface 21 in the inspection region 30. The main surface insulating film 33 includes at least one of a silicon oxide film, a silicon nitride film, and a silicon oxynitride film. The main surface insulating film 33 preferably has a single layer structure formed by a silicon oxide film. The main surface insulating film 33 particularly preferably includes a silicon oxide film made of oxide of the semiconductor wafer 20.

The main surface insulating film 33 has a contact opening 34 from which the inner side portion of the inspection region 30 and an inner peripheral portion of the guard region 32 are exposed. The main surface insulating film 33 covers the inner side portion of the inspection region 30 at an interval inward from the peripheral edge of the inspection region 30, and exposes the first main surface 21 (second semiconductor region 26) from a peripheral edge portion of the inspection region 30. That is, the main surface insulating film 33 exposes a boundary portion between the plurality of inspection regions 30. As a matter of course, the main surface insulating film 33 may cover the peripheral edge portion of the inspection region 30 (boundary portion between the plurality of inspection regions 30).

The semiconductor structure 2A for inspection includes a first main surface electrode 40 having a first hardness (Vickers hardness [unit: Hv]) and covering the first main surface 21 in the inspection region 30. The first hardness may be not less than 15 Hv and not more than 150 Hv. The first main surface electrode 40 is arranged at an interval inward from the peripheral edge of the inspection region 30. In this embodiment, the first main surface electrode 40 is formed in a square shape along the peripheral edge of the inspection region 30 in a plan view. The first main surface electrode 40 enters the contact opening 34 from above the main surface insulating film 33, and is electrically connected to the first main surface 21 and an inner edge portion of the guard region 32. The first main surface electrode 40 forms a Schottky junction with the second semiconductor region 26 (first main surface 21).

A thickness of the first main surface electrode 40 may be not less than 1 μm and not more than 5.3 μm. The first main surface electrode 40 is preferably formed by a metal film other than a plated film. In this embodiment, the first main surface electrode 40 has a laminated structure including a first metal film 41 and a second metal film 42 laminated in this order from the first main surface 21 side. Both the first metal film 41 and the second metal film 42 are formed by a sputtering process.

The first metal film 41 is formed by a relatively thin metal barrier film forming a Schottky barrier together with the first main surface 21 (second semiconductor region 26). In this embodiment, the first metal film 41 includes a Ti-based metal film. The first metal film 41 may have a single layer structure formed by a Ti film or a TiN film. The first metal film 41 may have a laminated structure including a Ti film and a TiN film in an arbitrary order. The first metal film 41 may have a thickness of not less than 10 nm and not more than 300 nm.

The second metal film 42 is formed by an Al-based metal film forming a main body of the first main surface electrode 40, and has the first hardness. The second metal film 42 may include at least one of a pure Al film (Al film having a purity of not less than 99%), an AlCu alloy film, an AlSi alloy film, and an AlSiCu alloy film. The second metal film 42 has a thickness exceeding the thickness of the first metal film 41. The thickness of the second metal film 42 may be not less than 1 μm and not more than 5 μm.

The semiconductor structure 2A for inspection includes an insulating film 50 covering the first main surface electrode 40 in the inspection region 30. The insulating film 50 covers a peripheral edge portion of the first main surface electrode 40 at an interval inward from the peripheral edge of the inspection region 30. The insulating film 50 partitions a pad opening 51 in the inner side portion of the inspection region 30, and partitions a street opening 52 in the peripheral edge portion of the inspection region 30.

The pad opening 51 exposes an inner side portion of the first main surface electrode 40. In this embodiment, the pad opening 51 is partitioned in a square shape along a peripheral edge of the first main surface electrode 40 in a plan view. The street opening 52 extends along the peripheral edge of the inspection region 30, and exposes the first main surface 21. Specifically, the street opening 52 is partitioned in a grid shape extending in the first direction X and the second direction Y by the plurality of insulating films 50 adjacent to each other in the first direction X and the second direction Y, and exposes the boundary portion between the plurality of inspection regions 30. In a case where the main surface insulating film 33 covering the peripheral edge portion of the inspection region 30 is formed, the insulating film 50 partitions the street opening 52 from which the main surface insulating film 33 is exposed.

The insulating film 50 is preferably thicker than the first main surface electrode 40. A thickness of the insulating film 50 may be not less than 5.5 μm and not more than 25 μm. In this embodiment, the insulating film 50 has a laminated structure including an inorganic insulating film 53 (inorganic film) and an organic insulating film 54 (organic film) laminated in this order from the first main surface electrode 40 side. The inorganic insulating film 53 includes at least one of a silicon oxide film, a silicon nitride film, and a silicon oxynitride film. The inorganic insulating film 53 preferably includes an insulating material different from the main surface insulating film 33. In this embodiment, the inorganic insulating film 53 is formed by a silicon nitride film.

The organic insulating film 54 forms a main body of the insulating film 50. The organic insulating film 54 is preferably made of light-sensitive resin. The organic insulating film 54 may be a negative type or may be a positive type. The organic insulating film 54 may include at least one of a polyimide film, a polyamide film, and a polybenzoxazole film. In this embodiment, the organic insulating film 54 is formed by a polybenzoxazole film.

The organic insulating film 54 may cover the inorganic insulating film 53 so that one of or both of an inner peripheral portion and an outer peripheral portion of the inorganic insulating film 53 are exposed. In this embodiment, the organic insulating film 54 exposes both the inner peripheral portion and the outer peripheral portion of the inorganic insulating film 53, and partitions the inorganic insulating film 53, and the pad opening 51 and the street opening 52. The organic insulating film 54 may cover the entire region of the inorganic insulating film 53. The inorganic insulating film 53 may have a thickness of not less than 0.5 μm and not more than 5 μm. The organic insulating film 54 is preferably thicker than the inorganic insulating film 53. A thickness of the organic insulating film 54 may be not less than 5 μm and not more than 20 μm.

The semiconductor structure 2A for inspection includes a protective electrode 60 having a second hardness (Vickers hardness [unit: Hv]) which exceeds the first hardness of the first main surface electrode 40 and covering the first main surface electrode 40 in the inspection region 30. The second hardness may exceed 150 Hv and may be not more than 700 Hv (preferably, not less than 500 Hv).

The protective electrode 60 is an object to be abutted with the probe needle 13, and is to be electrically connected to the probe needle 13. The protective electrode 60 protects the first main surface electrode 40, the functional device 31, the semiconductor wafer 20, etc., from damage due to an abutting action of the probe needle 13. Therefore, the second hardness preferably exceeds the hardness of the probe needle 13. The protective electrode 60 forms a current path between the second main surface 22 and the protective electrode 60 via the functional device 31 and the first main surface electrode 40.

The protective electrode 60 is formed on the first main surface electrode 40 at an interval inward from the peripheral edge of the inspection region 30. In this embodiment, the protective electrode 60 is arranged in the pad opening 51, and covers the inner side portion of the first main surface electrode 40. The protective electrode 60 has an electrode surface placed in the pad opening 51, and is not arranged outside of the pad opening 51. The electrode surface is an abutment surface with respect to the probe needle 13. The protective electrode 60 has a planar shape matching with the pad opening 51 in a plan view (square shape in this embodiment). The protective electrode 60 has an area less than an area of the first main surface electrode 40 in a plan view.

The protective electrode 60 covers the first main surface electrode 40 and a wall surface of the insulating film 50 in the pad opening 51. Specifically, the protective electrode 60 overlaps on an inner peripheral portion of the inorganic insulating film 53 from above the first main surface electrode 40 and covers the organic insulating film 54 in the pad opening 51. The protective electrode 60 is formed at an interval from an opening end of the pad opening 51 to the first main surface electrode 40 side so that part of a wall surface of the pad opening 51 is exposed. That is, the protective electrode 60 is thinner than the insulating film 50.

A thickness of the protective electrode 60 preferably exceeds a depth of an abutment mark of the probe needle 13. That is, the protective electrode 60 may have the abutment mark of the probe needle 13 after abutting with the probe needle 13. The depth of the abutment mark is defined to some extent by a specification (including a material and a shape) of the probe needle 13 and a pressure added from the probe needle 13 to the protective electrode 60. Also, the abutment mark is expanded by an increase in the number of times of abutments of the probe needle 13 with respect to the protective electrode 60. Therefore, the depth of the abutment mark may be defined by a depth of an accumulated abutment mark formed in a case where the probe needle 13 is abutted with the same point of the protective electrode 60 by the target number of times of abutments.

The target number of times of abutments of the probe needle 13 is preferably set to the target number of times of reuse of the semiconductor structure 2A for inspection. In this case, the protective electrode 60 is capable of withstanding the target number of times of reuse of the semiconductor structure 2A for inspection. In a case where the target number of times of reuse (target number of times of abutments) was set 400 times and the probe needle 13 was abutted with the same point of the protective electrode 60 400 times, the depth of the abutment mark generated in the protective electrode 60 was not less than 0.02 μm and not more than 0.04 μm. Therefore, the protective electrode 60 is preferably not less than 0.05 μm.

The thickness of the protective electrode 60 is preferably not more than 25 μm (preferably less than 25 μm) in consideration with the thickness of the insulating film 50. The thickness of the protective electrode 60 may be not more than 20 μm (preferably less than 20 μm) in consideration with the upper limit of the thickness of the organic insulating film 54. As a matter of course, the thickness of the protective electrode 60 may be not more than 10 μm. The thickness of the protective electrode 60 is preferably not less than the thickness of the inorganic insulating film 53 and not more than the thickness of the organic insulating film 54. The thickness of the protective electrode 60 particularly preferably exceeds the thickness of the inorganic insulating film 53 and is less than the thickness of the organic insulating film 54. Also, the protective electrode 60 is preferably thicker than the first main surface electrode 40.

The protective electrode 60 is preferably formed by a plated film. In this embodiment, the protective electrode 60 has a laminated structure including an Ni film 61 laminated on the first main surface electrode 40, a Pd film 62 laminated on the Ni film 61, and an Au film 63 laminated on the Pd film 62. The Ni film 61 is formed by an electroless plating process with the first main surface electrode 40 as a starting point. The Pd film 62 is formed by the electroless plating process with the Ni film 61 as a starting point. The Au film 63 is formed by the electroless plating process with the Pd film 62 as a starting point.

The Ni film 61 forms a main body of the protective electrode 60, and has the second hardness exceeding the first hardness of the first metal film 41 (Al-based metal film). The Ni film 61 preferably occupies not less than 60% and not more than 100% (in the embodiment, less than 100%) of the thickness of the protective electrode 60. Specifically, the Ni film 61 overlaps on the inner peripheral portion of the inorganic insulating film 53 from above the first main surface electrode 40 and is in contact with the organic insulating film 54 in the pad opening 51. The Ni film 61 is formed at an interval from the opening end of the pad opening 51 to the first main surface electrode 40 side so that part of the wall surface of the pad opening 51 is exposed.

The Ni film 61 may have a thickness of not less than 0.03 μm and not more than 25 μm (in this embodiment, not less than 0.03 μm and not more than 24.6 μm). The Ni film 61 preferably has a thickness of not less than 0.05 μm. The thickness of the Ni film 61 may be not more than 20 μm (preferably less than 20 μm). As a matter of course, the thickness of the Ni film 61 may be not more than 10 μm. The Ni film 61 preferably has a thickness exceeding the thickness of the first metal film 41 (Al-based metal film).

The Pd film 62 covers the Ni film 61 in a film shape and is in contact with the organic insulating film 54 in the pad opening 51. The Pd film 62 preferably has a thickness less than the thickness of the Ni film 61. The Pd film 62 preferably has a thickness of not less than 0.01 un and not more than 0.2 μm.

The Au film 63 covers the Pd film 62 in a film shape and is in contact with the organic insulating film 54 in the pad opening 51. The Au film 63 forms an electrode surface in the pad opening 51. The Au film 63 preferably has a thickness less than the thickness of the Ni film 61. The Au film 63 preferably has a thickness of not less than 0.01 μm and not more than 0.2 μm.

The protective electrode 60 is only required to include the Ni film 61, and the Pd film 62 and the Au film 63 are arbitrarily included. Therefore, the protective electrode 60 may have a single layer structure formed by the Ni film 61. In this case, the Ni film 61 may have a thickness of not less than 0.03 μm and not more than 25 μm (preferably, not less than 0.05 μm). Also, the protective electrode 60 may have a laminated structure including the Ni film 61 and the Au film 63 laminated in this order from the first main surface electrode 40 side.

Also, the protective electrode 60 may have a laminated structure including the Ni film 61 and the Pd film 62 laminated in this order from the first main surface electrode 40 side. Further, the protective electrode 60 may include a metal film other than the Pd film 62 and the Au film 63. For example, in a structure having the Au film 63, the protective electrode 60 may include an Ag film further covering the Au film 63. In this case, the Ag film covers the Au film 63 in a film shape and is in contact with the organic insulating film 54 in the pad opening 51. The Ag film forms an electrode surface.

The semiconductor structure 2A for inspection includes a second main surface electrode 65 covering the second main surface 22. The second main surface electrode 65 is an object to be in contact with the mounting surface 8a of the chuck stage 8 and is electrically connected to the mounting surface 8a. The second main surface electrode 65 covers the entire region of the second main surface 22, and forms an ohmic contact with the second main surface 22.

The second main surface electrode 65 forms a current path with each of the protective electrodes 60 via each of the functional devices 31. The second main surface electrode 65 may have a laminated structure including at least one of a Ti film, an Ni film, a Pd film, an Au film, and an Ag film. For example, the second main surface electrode 65 may have a laminated structure including a Ti film, an Ni film, a Pd film, and an Au film laminated in this order from the second main surface 22 side.

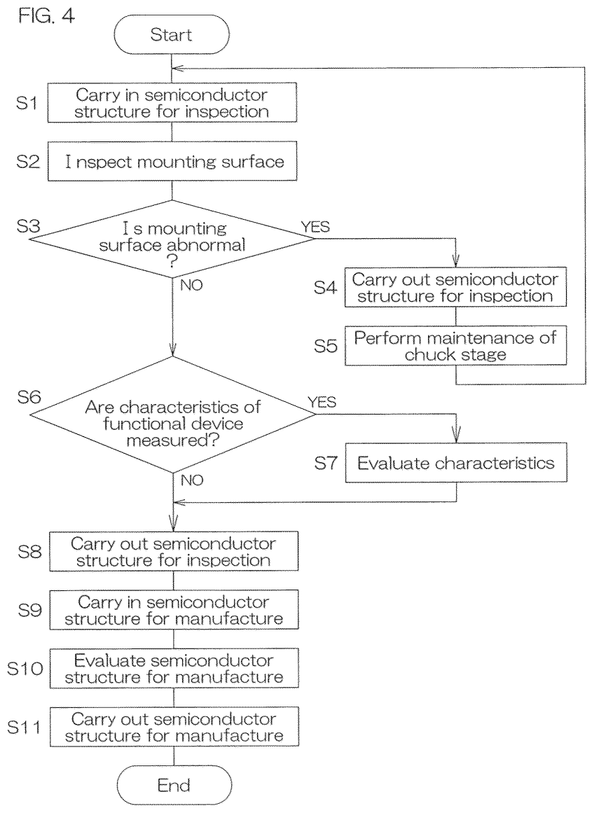

FIG. 4 is a flowchart for describing a manufacturing method of a semiconductor device by using the semiconductor evaluation device 1 shown in FIG. 1 and the semiconductor structure 2A for inspection shown in FIG. 2. FIGS. 5A to 5F are schematic views for describing the flowchart shown in FIG. 4. With reference to FIG. 4, the manufacturing method of the semiconductor device includes a step of inspecting the chuck stage 8 by using the semiconductor structure 2A for inspection (Steps S1 to S8), and a step of evaluating the semiconductor structure 2B for manufacture (see FIG. 5E) (Steps S9 to S11). Hereinafter, each of the steps will be specifically described.

With reference to FIG. 5A, in the step of inspecting the chuck stage 8, first, the semiconductor structure 2A for inspection is carried into the prober device 3 (Step S1 of FIG. 4). The semiconductor structure 2A for inspection is arranged on the mounting surface 8a in a posture that the second main surface electrode 65 (second main surface 22) is to be electrically connected to the mounting surface 8a of the chuck stage 8 and the protective electrodes 60 are connected to the probe needle 13.

Next, with reference to FIG. 5B, a step of inspecting the mounting surface 8a by the tester device 4 is executed (Step S2 of FIG. 4). In this step, the probe needle 13 is abutted with the protective electrode 60, and the mounting surface 8a and the probe needle 13 are to be energized via the semiconductor structure 2A for inspection. In this step, specifically, relative positions of the probe needle 13 and the semiconductor structure 2A for inspection are to be changed so that the probe needle 13 is to be successively abutted with the protective electrode 60 of each of the inspection regions 30, and an inspection current I1 is to be successively applied between the mounting surface 8a and the probe needle 13 from the tester device 4. An energization result of the mounting surface 8a and the probe needle 13 in each of the inspection regions 30 is to be input to the tester device 4.

Specifically, the energization result of each of the inspection regions 30 is any one of or both of the voltage value and the resistance value between the mounting surface 8a and the probe needle 13. The energization result of each of the inspection regions 30 (measurement result of the tester device 4) is to be input from the tester device 4 to the control device 5. The control device 5 judges that the mounting surface 8a is normal in a case where the energization result of each of the inspection regions 30 is normal, and judges that the mounting surface 8a is abnormal in a case where the energization result of each of the inspection regions 30 is abnormal. The case where the mounting surface 8a is abnormal includes a case where foreign substances adhere to the mounting surface 8a, a case where the mounting surface 8a is deteriorated, etc.

With reference to FIG. 5C, in a case where it is judged that the mounting surface 8a is abnormal (Step S3 of FIG. 4: YES), the semiconductor structure 2A for inspection is carried out from the prober device 3 (Step S4 of FIG. 4), and a step of performing maintenance of the chuck stage 8 is implemented (Step S5 of FIG. 4). The step of performing the maintenance of the chuck stage 8 may include a step of removing foreign substances from the mounting surface 8a, or a step of replacing the chuck stage 8 with another chuck stage 8. Thereafter, Steps S1 to S3 are implemented again.

In a case where the mounting surface 8a is normal (Step S3 of FIG. 4: NO), it may be judged whether the electrical characteristics of the functional device 31 (SBD in this embodiment) of the semiconductor structure 2A for inspection are measured or not (Step S6 of FIG. 4). With reference to FIG. 5D, in a case where the electrical characteristics of the functional device 31 are measured (Step S6 of FIG. 4: YES), a step of evaluating the electrical characteristics of the functional device 31 is executed by the tester device 4 (Step S7 of FIG. 4).

In this step, the probe needle 13 is to be abutted with the protective electrode 60, and the mounting surface 8a and the probe needle 13 are to be energized via the semiconductor structure 2A for inspection. In this step, specifically, the relative positions of the probe needle 13 and the semiconductor structure 2A for inspection are to be changed so that the probe needle 13 is to be successively abutted with the protective electrode 60 of each of the inspection regions 30, and an evaluation current I2 is to be successively applied between the mounting surface 8a and the probe needle 13. An energization result of the mounting surface 8a and the probe needle 13 in each of the inspection regions 30 is to be input to the tester device 4.

The evaluation current I2 for the functional device 31 is preferably larger than the inspection current I1 for the mounting surface 8a (I1<I2). For example, a breakdown current serving as the evaluation current I2 may be applied to the functional device 31, and a breakdown voltage serving as the energization result may be measured by the tester device 4. According to this step, it is possible to preliminarily inspect performances of the prober device 3 (particularly the mounting surface 8a and the probe needle 13) and the tester device 4 in a case where a large electric current and a large voltage are applied to the object to be measured, and it is possible to reduce a risk of failure in the subsequent steps.

Data of the electrical characteristics of the semiconductor structure 2A for inspection acquired in this step (the data may include a wafer map, etc.) may be utilized for evaluating electrical characteristics of the semiconductor structure 2B for manufacture to be subsequently evaluated. As an example, the data of the electrical characteristics of the semiconductor structure 2A for inspection may be compared with data of the electrical characteristics of the semiconductor structure 2B for manufacture. After evaluating the electrical characteristics of the functional device 31, the semiconductor structure 2A for inspection is carried out from the prober device 3 (Step S8 of FIG. 4). In a case where the electrical characteristics of the functional device 31 are not measured (Step S6 of FIG. 4: NO), the semiconductor structure 2A for inspection is carried out from the prober device 3 (Step S8 of FIG. 4).

After implementing the step of inspecting the chuck stage 8 (inspecting method), the step of evaluating the semiconductor structure 2B for manufacture (Steps S9 to S11) is implemented. With reference to FIG. 5E, in the step of evaluating the semiconductor structure 2B for manufacture, first, the semiconductor structure 2B for manufacture is carried into the prober device 3 (Step S9 of FIG. 4). The semiconductor structure 2B for manufacture preferably has the same structure as the semiconductor structure 2A for inspection.

That is, as well as the semiconductor structure 2A for inspection, the semiconductor structure 2B for manufacture preferably includes the semiconductor wafer 20 (wide-bandgap semiconductor wafer), the first semiconductor region 25, the second semiconductor region 26, the functional devices 31, the guard regions 32, the main surface insulating films 33, the first main surface electrodes 40, the insulating films 50, the protective electrodes 60, and the second main surface electrode 65. In the semiconductor structure 2B for manufacture, the plurality of inspection regions 30 are replaced with the “plurality of device regions (30).” The plurality of device regions (30) have a different property from the plurality of inspection regions 30 in a point that the device regions (30) are divided into individual pieces in a subsequent dicing step and become semiconductor devices.

According to this structure, it is possible to continuously evaluate the semiconductor structure 2B for manufacture by using the same equipment and the same settings as the semiconductor structure 2A for inspection subsequent to the step of inspecting the chuck stage 8. Thus, it is possible to reduce the man-hours for manufacturing. As a matter of course, the semiconductor structure 2B for manufacture may have a different structure (such as different functional devices 31) from the semiconductor structure 2A for inspection.

The semiconductor structure 2B for manufacture is to be arranged on the mounting surface 8a in a posture that the second main surface electrode 65 (second main surface 22) is to be electrically connected to the mounting surface 8a of the chuck stage 8 and the protective electrodes 60 are to be connected to the probe needle 13. In the step of evaluating the semiconductor structure 2B for manufacture, since the mounting surface 8a is preliminarily inspected, failure of the semiconductor structure 2B for manufacture due to foreign substances, etc., on the mounting surface 8a is suppressed. Therefore, in the semiconductor structure 2B for manufacture including the semiconductor wafer 20 (wide-bandgap semiconductor wafer) which is more expensive than the Si wafer, it is possible to avoid an increase in manufacturing cost due to the failure.

Next, with reference to FIG. 5F, a step of evaluating the electrical characteristics of the semiconductor structure 2B for manufacture is executed by the tester device 4 (Step S10 of FIG. 4). In this step, the probe needle 13 is to be abutted with the protective electrode 60, and the mounting surface 8a and the probe needle 13 are to be energized via the semiconductor structure 2B for manufacture. In this step, specifically, relative positions of the probe needle 13 and the semiconductor structure 2B for manufacture are to be changed so that the probe needle 13 is to be successively abutted with the protective electrode 60 of each of the device regions (30), and an evaluation current I3 is to be successively applied between the mounting surface 8a and the probe needle 13 from the tester device 4. An energization result of the mounting surface 8a and the probe needle 13 in each of the device regions (30) is to be input to the tester device 4.

The evaluation current I3 for the semiconductor structure 2B for manufacture is preferably larger than the inspection current I1 for the mounting surface 8a (I1<I3). The evaluation current I3 for the semiconductor structure 2B for manufacture is particularly preferably the same as the evaluation current I2 for the semiconductor structure 2A for inspection (I2=I3). With regard to the semiconductor structure 2B for manufacture, a breakdown current serving as the evaluation current I3 may be applied to the functional device 31, and a breakdown voltage serving as the energization result may be measured by the tester device 4.

The energization result of each of the device regions (30) is to be input from the tester device 4 to the control device 5. The control device 5 judges that the electrical characteristics of the semiconductor structure 2B for manufacture are normal in a case where the energization result of each of the device regions (30) is normal, and judges that the electrical characteristics of the semiconductor structure 2B for manufacture are abnormal in a case where the energization result of each of the device regions (30) is abnormal. Thereafter, the semiconductor structure 2B for manufacture is carried out from the prober device 3 (Step S11 of FIG. 4), and the dicing step is implemented. After the steps including the steps above, the semiconductor devices are manufactured.

The step of inspecting the mounting surface 8a (Steps S1 to S8 of FIG. 4) is implemented at arbitrary timing such as the time of starting up the semiconductor evaluation device 1 or the time after carrying out the semiconductor structure 2B for manufacture, and the semiconductor structure 2A for inspection is reused in each case. That is, the semiconductor structure 2A for inspection is used on the premise of reuse of a long time, and the manufacturing method of the semiconductor device includes a step of reusing the semiconductor structure 2A for inspection. The step of evaluating the electrical characteristics of the functional device 31 (Step S7 of FIG. 4) is a mode of the step of reusing the semiconductor structure 2A for inspection.

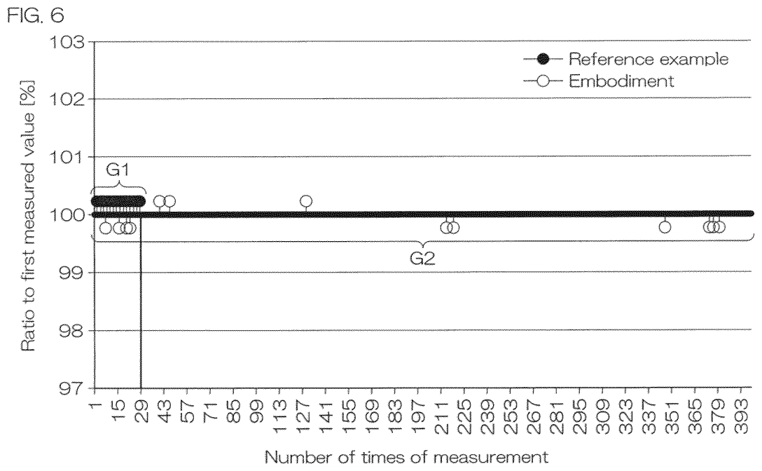

FIG. 6 is a graph showing the reliability of the semiconductor structure 2A for inspection shown in FIG. 2. In FIG. 6, the vertical axis indicates a ratio to a first measured value [%], and the horizontal axis indicates the number of times of measurements. FIG. 6 shows a first plot group G1 arranged by black circles, and a second plot group G2 arranged by white circles. The first plot group G1 shows measurement results of a semiconductor structure for inspection according to a reference example (not shown), and the second plot group G2 shows measurement results of the semiconductor structure 2A for inspection according to the first embodiment. The semiconductor structure for inspection according to the reference example has the same structure as the semiconductor structure 2A for inspection according to the first embodiment except for a point of having no protective electrodes 60.

With reference to the first plot group G1, in a case of the semiconductor structure for inspection according to the reference example, after reuse of about 30 times, the measured value became abnormal, and the semiconductor structure for inspection became unable to be reused any more. On the other hand, with reference to the second plot group G2, in a case of the semiconductor structure 2A for inspection according to the first embodiment, even after reuse of more than 30 times, no abnormality was found in the measured value, and the semiconductor structure 2A for inspection was able to be reused for 100 times or more. Although the target number of times of reuse was set 400 times and the semiconductor structure 2A for inspection was reused for 400 times, the measured value was stable.

The semiconductor structure for inspection according to the reference example have no protective electrodes 60. Therefore, an abutment mark due to an abutment of the probe needle 13 is generated in the first main surface electrode 40. In some cases, the abutment mark passes through the first main surface electrode 40 and reaches the semiconductor wafer 20. This type of abutment mark is accumulated by reuse and causes abnormality in the measured value. The semiconductor structure for inspection according to the reference example has a relatively poor reliability, and needs to be replaced before reaching the number of times of reuse which is presumed to cause abnormality. That is, in the semiconductor structure for inspection according to the reference example, the replacement frequency (that is, the number of manufactured semiconductor structures for inspection) is increased and the manufacturing cost is increased.

Meanwhile, the semiconductor structure 2A for inspection according to the first embodiment includes the semiconductor wafer 20 (semiconductor plate), the inspection regions 30, the first main surface electrodes 40, and the protective electrodes 60. The semiconductor wafer 20 has the first main surface 21 on one side and the second main surface 22 on the other side. The inspection regions 30 are provided in the first main surface 21. The first main surface electrodes 40 have the first hardness and cover the first main surface 21 in the inspection regions 30.

The protective electrodes 60 have the second hardness exceeding the first hardness, cover the first main surface electrodes 40 in the inspection regions 30, and form the current paths between the second main surface 22 and the protective electrodes 60 via the semiconductor wafer 20. According to this structure, it is possible to protect the first main surface electrodes 40 and the semiconductor wafer 20 from the abutment mark of the probe needle 13 by the relatively-hard protective electrodes 60. Thereby, it is possible to suppress a variation of the measured value due to the abutment mark. Thus, it is possible to reuse the semiconductor structure 2A for inspection for a long time. Therefore, it is possible to provide the highly reliable semiconductor structure 2A for inspection.

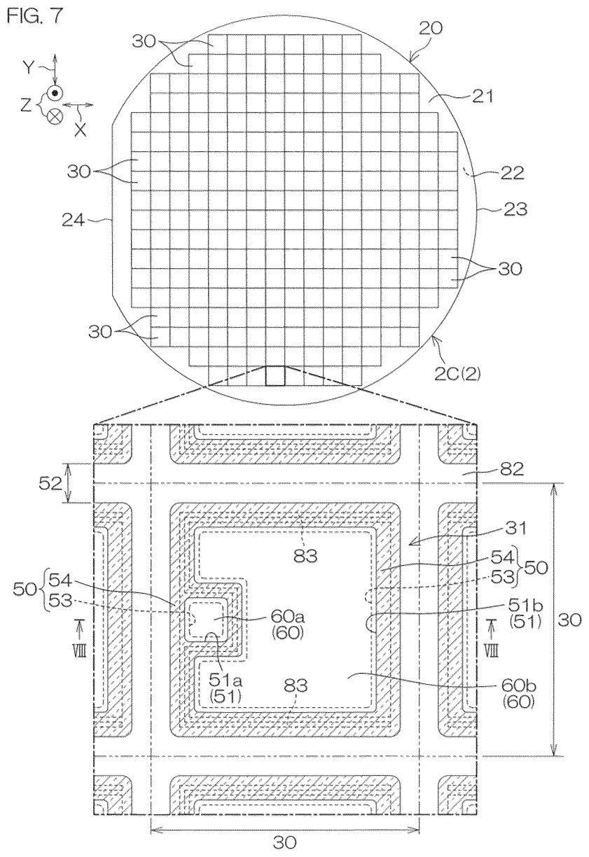

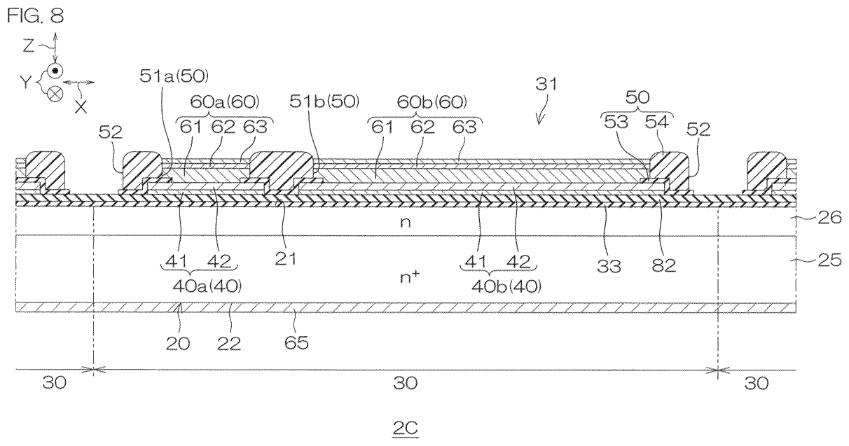

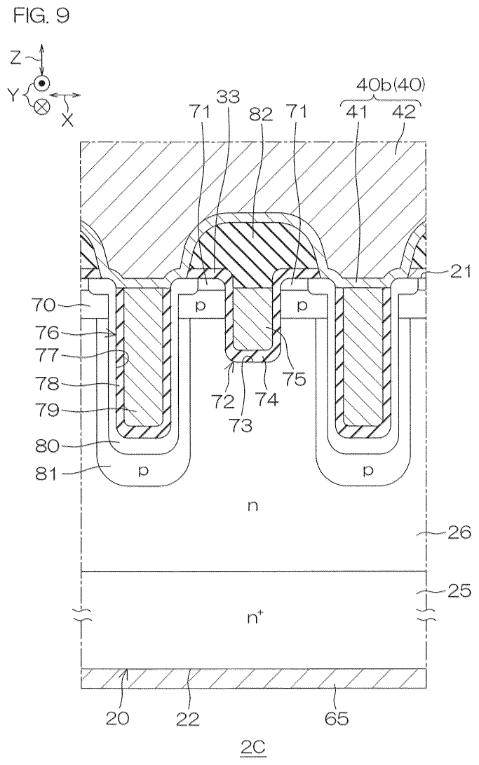

FIG. 7 is a plan view showing a semiconductor structure 2C for inspection according to a second embodiment. FIG. 8 is a sectional view taken along line VIII-VIII shown in FIG. 7. FIG. 9 is a sectional view in which major parts of the functional device 31 shown in FIG. 7 are enlarged.

With reference to FIGS. 7 to 9, the semiconductor structure 2C for inspection has a different structure from the semiconductor structure 2A for inspection described above in a point that the functional device 31 includes a metal insulator semiconductor field effect transistor (MISFET) in place of the SBD. In this embodiment, the MISFET is of a trench gate type. Hereinafter, different points from the semiconductor structure 2A for inspection in the semiconductor structure 2C for inspection will be described. Also, since the plurality of inspection regions 30 (functional devices 31) have the same structure, a structure of a single inspection region 30 (functional device 31) will be described below.

The semiconductor structure 2C for inspection includes a p-type body region 70 formed in a surface layer portion of a first main surface 21 in the inspection region 30. The body region 70 is formed in a surface layer portion of the second semiconductor region 26 at an interval from a bottom portion of the second semiconductor region 26 to the first main surface 21 side. The semiconductor structure 2C for inspection includes an n-type source region 71 formed in a surface layer portion of the body region 70. The source region 71 has an n-type impurity concentration higher than the second semiconductor region 26. The source region 71 forms a channel of the second semiconductor region 26 and the MISFET in the body region 70.

The semiconductor structure 2C for inspection includes a plurality of trench gate structures 72 formed in the first main surface 21 in the inspection region 30. The plurality of trench gate structures 72 control inversion and non-inversion of the channel. The plurality of trench gate structures 72 pass through the body region 70 and the source region 71 and reach the second semiconductor region 26. The plurality of trench gate structures 72 are allocated at intervals from each other in the first direction X and respectively formed in a band shape extending in the second direction Y in a plan view.

Each of the trench gate structures 72 includes a gate trench 73, a gate insulating film 74, and a gate electrode 75. The gate trench 73 is formed in the first main surface 21. The gate insulating film 74 covers a wall surface of the gate trench 73. The gate electrode 75 is embedded in the gate trench 73 across the gate insulating film 74. The gate electrode 75 opposes the channel across the gate insulating film 74.

The semiconductor structure 2C for inspection includes a plurality of trench source structures 76 formed in the first main surface 21 in the inspection region 30. Each of the plurality of trench source structures 76 is allocated between the two trench gate structures 72 in the vicinity of each other on the first main surface 21. The plurality of trench source structures 76 may be respectively formed in a band shape extending in the second direction Y in a plan view. The plurality of trench source structures 76 pass through the body region 70 and the source region 71 and reach the second semiconductor region 26. The plurality of trench source structures 76 have a depth exceeding a depth of the trench gate structures 72.

Each of the trench source structures 76 includes a source trench 77, a source insulating film 78, and a source electrode 79. The source trench 77 is formed in the first main surface 21. The source insulating film 78 covers a wall surface of the source trench 77. The source electrode 79 is embedded in the source trench 77 across the source insulating film 78.

The semiconductor structure 2C for inspection includes a plurality of p-type contact regions 80 respectively formed in regions along the plurality of trench source structures 76 in the inspection region 30. The plurality of contact regions 80 have a p-type impurity concentration higher than the body region 70. Each of the contact regions 80 covers a side wall and a bottom wall of each of the trench source structures 76, and is electrically connected to the body region 70.

The semiconductor structure 2C for inspection includes a plurality of p-type well regions 81 respectively formed in regions along the plurality of trench source regions 76 in the inspection region 30. Each of the well regions 81 has a p-type impurity concentration higher than the body region 70 and lower than the contact regions 80. Each of the well regions 81 covers the corresponding trench source structure 76 across the corresponding contact region 80. Each of the well regions 81 covers a side wall and a bottom wall of the corresponding trench source structure 76 and is electrically connected to the body region 70.

The semiconductor structure 2C for inspection includes the main surface insulating film 33 described above, the main surface insulating film covering the first main surface 21 in the inspection region 30. The main surface insulating film 33 continues to the gate insulating film 74 and the source insulating film 78, and exposes the gate electrode 75 and the source electrode 79. In this embodiment, the main surface insulating film 33 covers the peripheral edge portion of the inspection region 30 (boundary portion between the plurality of inspection regions 30). As a matter of course, the main surface insulating film 33 may expose the peripheral edge portion of the inspection region 30 (boundary portion between the plurality of inspection regions 30).

The semiconductor structure 2C for inspection includes an interlayer insulating film 82 covering the main surface insulating film 33 in the inspection region 30. The interlayer insulating film 82 may include at least one of a silicon oxide film, a silicon nitride film, and a silicon oxynitride film. The interlayer insulating film 82 covers the plurality of trench gate structures 72 and the plurality of trench source structures 76. In this embodiment, the interlayer insulating film 82 covers the peripheral edge portion of the inspection region 30 (boundary portion between the plurality of inspection regions 30) across the main surface insulating film 33. As a matter of course, the interlayer insulating film 82 may expose the first main surface 21 or the main surface insulating film 33 in the peripheral edge portion of the inspection region 30 (boundary portion between the plurality of inspection regions 30).

The semiconductor structure 2C for inspection includes the plurality of first main surface electrodes 40 described above, the first main surface electrodes covering the interlayer insulating film 82 in the inspection region 30. The plurality of first main surface electrodes 40 have the laminated structure including the first metal film 41 and the second metal film 42 laminated in this order from the first main surface 21 side as well as the case of the first embodiment. In this embodiment, the first metal film 41 forms an ohmic contact with the first main surface 21.

The plurality of first main surface electrodes 40 include a gate main surface electrode 40a and a source main surface electrode 40b. In this embodiment, the gate main surface electrode 40a is arranged in a region in the vicinity of a central portion of one side of the inspection region 30 in a plan view. The gate main surface electrode 40a may be arranged in a corner portion of the inspection region 30 in a plan view. In this embodiment, the gate main surface electrode 40a is formed in a square shape in a plan view.

The source main surface electrode 40b is arranged on the interlayer insulating film 82 at an interval from the gate main surface electrode 40a. In this embodiment, the source main surface electrode 40b is formed in a polygonal shape having a concave portion recessed along the gate main surface electrode 40a in a plan view. As a matter of course, the source main surface electrode 40b may be formed in a square shape in a plan view. The source main surface electrode 40b passes through the interlayer insulating film 82 and the main surface insulating film 33, and is electrically connected to the plurality of trench source structures 76, the source region 71, and the plurality of well regions 81.

The semiconductor structure 2C for inspection includes a gate wiring electrode 83 routed from the gate main surface electrode 40a to above the interlayer insulating film 82 in the inspection region 30. The gate wiring electrode 83 has the laminated structure including the first metal film 41 and the second metal film 42 laminated in this order from the first main surface 21 side as well as the plurality of first main surface electrodes 40. The gate wiring electrode 83 is formed in a band shape extending along a peripheral edge of the inspection region 30 so as to cross (specifically, to be orthogonal to) end portions of the plurality of trench gate structures 72 in a plan view. The gate wiring electrode 83 passes through the interlayer insulating film 82 and is electrically connected to the plurality of trench gate structures 72.

The semiconductor structure 2C for inspection includes the insulating film 50 described above, the insulating film covering the plurality of first main surface electrodes 40 in the inspection region 30. The insulating film 50 has the laminated structure including the inorganic insulating film 53 and the organic insulating film 54 laminated in this order from the first main surface electrodes 40 side as well as the case of the first embodiment. In this embodiment, the insulating film 50 covers a peripheral edge portion of the gate main surface electrode 40a and a peripheral edge portion of the source main surface electrode 40b at an interval inward from the peripheral edge of the inspection region 30. The insulating film 50 covers the entire region of the gate wiring electrode 83.

The insulating film 50 partitions the plurality of pad openings 51 from which an inner side portion of the gate main surface electrode 40a and an inner side portion of the source main surface electrode 40b are exposed in an inner side portion of the inspection region 30, and partitions the street opening 52 from which the interlayer insulating film 82 is exposed in the peripheral edge portion of the inspection region 30. In this embodiment, the plurality of pad openings 51 include a gate pad opening 51a from which the inner side portion of the gate main surface electrode 40a is exposed, and a source pad opening 51b from which the inner side portion of the source main surface electrode 40b is exposed.

In this embodiment, the gate pad opening 51a is partitioned in a square shape along a peripheral edge of the gate main surface electrode 40a in a plan view. In this embodiment, the source pad opening 51b is formed in a polygonal shape along a peripheral edge of the source main surface electrode 40b in a plan view. The street opening 52 is formed in the same mode as the first embodiment.

The organic insulating film 54 may cover the inorganic insulating film 53 so that any one of or both of the inner peripheral portion and the outer peripheral portion of the inorganic insulating film 53 are exposed. In this embodiment, the organic insulating film 54 exposes both the inner peripheral portion and the outer peripheral portion of the inorganic insulating film 53, and partitions the inorganic insulating film 53, and the plurality of pad openings 51 and the street opening 52. The organic insulating film 54 may cover the entire region of the inorganic insulating film 53.

The semiconductor structure 2C for inspection includes the plurality of protective electrodes 60 described above, the protective electrodes respectively covering the plurality of first main surface electrodes 40 in the inspection region 30. The plurality of protective electrodes 60 include at least one of the Ni film 61, the Pd film 62, the Au film 63, and the Ag film as well as the case of the first embodiment. In this embodiment, the plurality of protective electrodes 60 include a gate protective electrode 60a and a source protective electrode 60b.

The gate protective electrode 60a is formed on the gate main surface electrode 40a at an interval inward from the peripheral edge of the gate main surface electrode 40a. The gate protective electrode 60a forms a current path reaching the gate electrode 75 via the gate main surface electrode 40a and the gate wiring electrode 83. In this embodiment, the gate protective electrode 60a is arranged in the gate pad opening 51a and covers the inner side portion of the gate main surface electrode 40a.

The gate protective electrode 60a has a gate electrode surface placed in the gate pad opening 51a, and is not arranged outside of the gate pad opening 51a. The gate electrode surface is an abutment surface with respect to the probe needle 13. The gate protective electrode 60a is formed in a planar shape matching with the gate pad opening 51a in a plan view (square shape along the peripheral edge of the gate main surface electrode 40a in this embodiment). The gate protective electrode 60a has an area less than an area of the gate main surface electrode 40a in a plan view.

The gate protective electrode 60a covers the gate main surface electrode 40a and the wall surface of the insulating film 50 in the gate pad opening 51a. Specifically, the gate protective electrode 60a overlaps on the inner peripheral portion of the inorganic insulating film 53 from above the gate main surface electrode 40a and covers the organic insulating film 54 in the gate pad opening 51a. The gate protective electrode 60a is formed at an interval from an opening end of the gate pad opening 51a to the gate main surface electrode 40a side so that part of a wall surface of the gate pad opening 51a is exposed. That is, the gate protective electrode 60a is thinner than the insulating film 50.

The source protective electrode 60b is formed on the source main surface electrode 40b at an interval inward from the peripheral edge of the source main surface electrode 40b. The source protective electrode 60b forms a current path between the second main surface 22 and the source protective electrode 60b via the functional device 31 and the source main surface electrode 40b. In this embodiment, the source protective electrode 60b is arranged in the source pad opening 51b and covers the inner side portion of the source main surface electrode 40b.

The source protective electrode 60b has a source electrode surface placed in the source pad opening 51b, and is not arranged outside of the source pad opening 51b. The source electrode surface is an abutment surface with respect to the probe needle 13. The source protective electrode 60b is formed in a planar shape matching with the source pad opening 51b in a plan view (polygonal shape having a concave portion in this embodiment). The source protective electrode 60b has an area less than an area of the source main surface electrode 40b in a plan view.

The source protective electrode 60b covers the source main surface electrode 40b and the wall surface of the insulating film 50 in the source pad opening 51b. Specifically, the source protective electrode 60b overlaps on the inner peripheral portion of the inorganic insulating film 53 from above the source main surface electrode 40b and covers the organic insulating film 54 in the source pad opening 51b. The source protective electrode 60b is formed at an interval from an opening end of the source pad opening 51b to the source main surface electrode 40b side so that part of a wall surface of the source pad opening 51b is exposed. That is, the source protective electrode 60b is thinner than the insulating film 50.

The semiconductor structure 2C for inspection includes the second main surface electrode 65 described above, the second main surface electrode covering the second main surface 22. In this embodiment, the second main surface electrode 65 forms a current path between each of the source protective electrodes 60b and the second main surface electrode 65 via each of the functional devices 31.

The steps shown in FIGS. 4 to 5F are also applied to the semiconductor structure 2C for inspection. In this case, the prober device 3 includes at least two probe units 7. Specifically, the at-least-two probe units 7 include at least one probe unit 7 for gate, and at least one probe unit 7 for source. The probe unit 7 for gate includes a probe needle 13 for gate to be abutted with the gate protective electrode 60a. The probe unit 7 for source includes a probe needle 13 for source to be abutted with the source protective electrode 60b.

In the step of inspecting the mounting surface 8a, a gate signal is applied from the probe needle 13 for gate to the gate protective electrode 60a, and a drain and source current serving as the inspection current I1 is applied between the mounting surface 8a and the probe needle 13 for source. The tester device 4 measures any one of or both of a voltage value and a resistance value between the mounting surface 8a and the probe needle 13 for source based on an energization result of the mounting surface 8a and the probe needle 13 for source as well as the case of the first embodiment.

The semiconductor structure 2B for manufacture (see FIG. 5E) to be evaluated after the step of inspecting the chuck stage 8 (mounting surface 8a) preferably has the same structure as the semiconductor structure 2C for inspection. That is, as well as the semiconductor structure 2C for inspection, the semiconductor structure 2B for manufacture preferably includes the semiconductor wafer 20 (wide-bandgap semiconductor wafer), the first semiconductor region 25, the second semiconductor region 26, the functional devices 31 (MISFETs), the main surface insulating films 33, the first main surface electrodes 40 (the gate main surface electrode 40a and the source main surface electrode 40b), the insulating films 50, the protective electrodes 60 (the gate protective electrode 60a and the source protective electrode 60b), the second main surface electrode 65, the body regions 70, the source regions 71, the trench gate structures 72, the trench source structures 76, the contact regions 80, the well regions 81, the interlayer insulating films 82, and the gate wiring electrodes 83. In the semiconductor structure 2B for manufacture, the plurality of inspection regions 30 are replaced with the “plurality of device regions (30).”

As described above, even in a case where the semiconductor structure 2C for inspection is applied to the semiconductor evaluation device 1, the same operations and effects as the operations and effects described in the first embodiment are exerted.

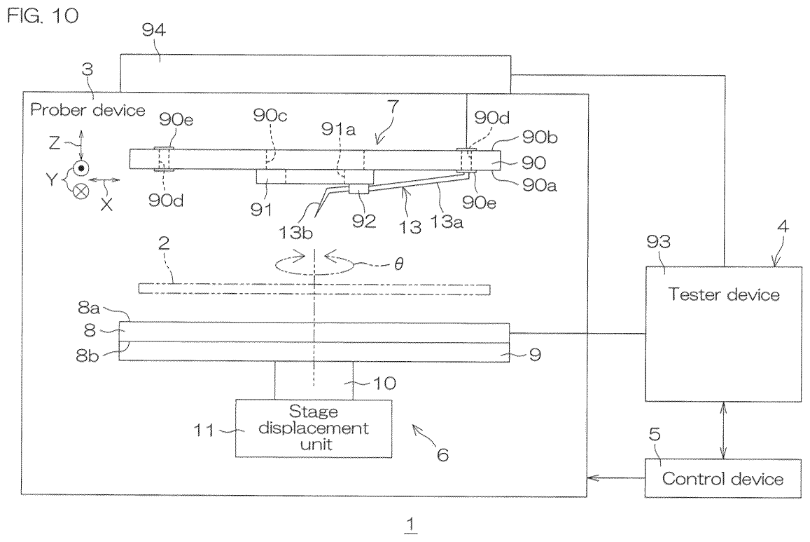

Hereinafter, the other example embodiments of the semiconductor evaluation device 1 will be shown. FIG. 10 is a schematic view showing a second example embodiment of the semiconductor evaluation device 1 shown in FIG. 1. FIG. 1 described above shows the example that the prober device 3 includes the probe unit 7 of the manipulator type. However, as shown in FIG. 10, the prober device 3 may include a probe unit 7 of a cantilever type. In this embodiment, the probe unit 7 includes a card substrate 90, a support portion 91, at least one probe needle 13, and a fixing portion 92.

The card substrate 90 is formed by a printed circuit board (PCB) made of resin. The card substrate 90 is arranged at a height position separated from the semiconductor structure 2 in the vertical direction Z in a state where the semiconductor structure 2 is arranged on the mounting surface 8a of the chuck stage 8. In this embodiment, the card substrate 90 has a first plate surface 90a opposing the mounting surface 8a (semiconductor structure 2) and a second plate surface 90b on the opposite side to the first plate surface 90a, and is formed in a ring-shaped (such as circular ring-shaped or square ring-shaped) plate shape having a through hole 90c in a central portion. Also, the card substrate 90 includes at least one via hole 90d, and a wiring 90e selectively routed to the first plate surface 90a and the second plate surface 90b via the via hole 90d.

The support portion 91 is formed by a ring-shaped (such as circular ring-shaped or square ring-shaped) insulating plate (such as ceramic plate) having a through hole 91a in a central portion, and arranged on the first plate surface 90a side in a posture parallel to the first plate surface 90a. The support portion 91 is arranged in a part facing the through hole 90c on the first plate surface 90a side so that the through hole 91a communicates with the through hole 90c of the card substrate 90.

The probe needle 13 is arranged on the first plate surface 90a side of the card substrate 90 so as to be supported by the support portion 91, and is electrically connected to the wiring 90e. In this embodiment, the probe needle 13 is formed in an L shape having a first part 13a which extends along the first plate surface 90a, and a second part 13b which extends toward the mounting surface 8a. The first part 13a has a base end inserted into the via hole 90d and connected to the wiring 90e. The first part 13a extends from the via hole 90d toward the through hole 90c so as to cross the support portion 91. The second part 13b is placed in a part facing the through hole 90c of the card substrate 90 (through hole 91a of the support portion 91), and has a sharp needle tip to be abutted with the semiconductor structure 2.

The number of the probe needles 13 is adjusted in accordance with the number of electrodes (abutment points) of the inspection object portion of the semiconductor structure 2. In a case where the inspection object portion of the semiconductor structure 2 has a plurality of electrodes allocated in an array shape, the plurality of probe needles 13 are attached in an array shape on the first plate surface 90a side corresponding to the plurality of electrodes. In a case where the inspection object portion of the semiconductor structure 2 has a single electrode, one or a plurality of probe needles 13 are attached on the first plate surface 90a side.

The fixing portion 92 is made of an insulating body (such as resin), and fixes the probe needle 13 to the support portion 91. Specifically, the fixing portion 92 fixes the first part 13a of the probe needle 13 to the support portion 91.

As well as the embodiments described above, the tester device 4 is electrically connected to the mounting surface 8a and the probe needle 13, gives a predetermined electric signal between the mounting surface 8a and the probe needle 13, and acquires an energization result between the mounting surface 8a and the probe needle 13. In this embodiment, the tester device 4 includes a tester main body 93 and a tester head 94. The tester main body 93 is a part that generates the electric signal to be given between the mounting surface 8a and the probe needle 13, and acquires the energization result between the mounting surface 8a and the probe needle 13.

The tester head 94 is detachably provided with respect to the prober device 3 and electrically connected to the tester main body 93. The tester head 94 is attached to the prober device 3 so as to oppose the mounting surface 8a across the probe unit 7. The tester head 94 has at least one contact portion to be electrically connected to the card substrate 90 (wiring 90e), and is electrically connected to the probe needle 13 via the wiring 90e. The tester head 94 gives an electric signal from the tester main body 93 to the probe needle 13, and gives an electric signal from the probe needle 13 (energization result) to the tester main body 93. The tester head 94 may be configured to convert the electric signal given from the tester main body 93 and/or the probe needle 13 into another electric signal and output the electric signal.

In a case where the probe unit 7 of the cantilever type is applied to the semiconductor structure 2C for inspection according to the second embodiment, the probe unit 7 includes at least two probe needles 13. Specifically, the at-least-two probe needles 13 include at least one probe needle 13 for gate to be abutted with the gate protective electrode 60a, and at least one probe needle 13 for source to be abutted with the source protective electrode 60b. As described above, even in a case where the probe unit 7 of the cantilever type is adopted, the same effects as the effects exerted in each of the embodiments described above are exerted.

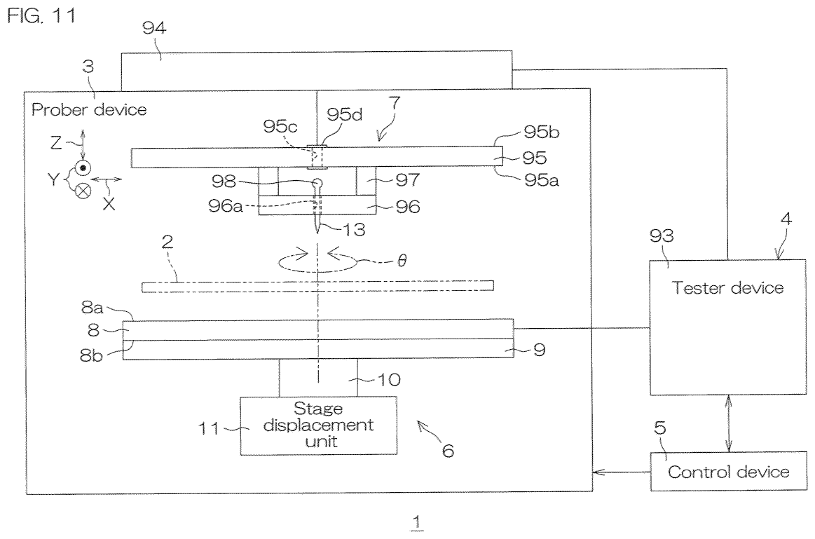

FIG. 11 is a schematic view showing a third example embodiment of the semiconductor evaluation device 1 shown in FIG. 1. FIG. 10 shows the probe unit 7 of the cantilever type. However, as shown in FIG. 11, the prober device 3 may include a probe unit 7 of a vertical type. In this embodiment, the probe unit 7 includes a card substrate 95, a support plate 96, a support portion 97, and at least one probe needle 13.

The card substrate 95 is formed by a PCB made of resin. The card substrate 95 is arranged at a height position separated from the semiconductor structure 2 in the vertical direction Z in a state where the semiconductor structure 2 is arranged on the mounting surface 8a of the chuck stage 8. In this embodiment, the card substrate 95 is formed in a disc shape having a first plate surface 95a which opposes the mounting surface 8a (semiconductor structure 2), and a second plate surface 95b on the opposite side to the first plate surface 95a. The card substrate 95 includes at least one via hole 95c, and a wiring 95d selectively routed to the first plate surface 95a and the second plate surface 95b via the via hole 95c.

The support plate 96 is formed by an insulating plate (such as a ceramic plate) and arranged on the first plate surface 95a side in a posture parallel to the first plate surface 95a. The support plate 96 has an insertion hole 96a in a part opposing the via hole 95c of the card substrate 95. The support portion 97 is fixed to the card substrate 95 and supports the support plate 96 at a position separated from the first plate surface 95a to the mounting surface 8a side.

In this embodiment, the probe needle 13 is formed in a needle shape extending linearly. The probe needle 13 is supported in an upstanding posture along the vertical direction Z by the support plate 96 on the first plate surface 95a side. Specifically, the probe needle 13 is arranged in the insertion hole 96a of the support plate 96 so that a gap is formed between the wiring 95d and the probe needle 13. The probe needle 13 has a base end placed on the first plate surface 95a side with respect to the support plate 96 and a sharp needle tip placed on the mounting surface 8a side with respect to the support plate 96, and is movably held by the support plate 96.

The probe needle 13 has a retaining portion 98 that prevents drop-off from the support plate 96. The retaining portion 98 may be provided in the gap between the wiring 95d and the probe needle 13. The retaining portion 98 may be configured to be abutted with part of the support plate 96 (second plate surface 95b). In this embodiment, the retaining portion 98 is provided in the base end of the probe needle 13 and formed by a wide portion having a larger width than a hole diameter of the insertion hole 96a. The retaining portion 98 may be formed by a bent portion of the probe needle 13 or may be formed by a different member from the probe needle 13.

Due to an abutting action with respect to the semiconductor structure 2, an external force toward the card substrate 95 is added to the probe needle 13. In this case, the probe needle 13 is moved toward the card substrate 95 side and abutted with the wiring 95d. Thereby, the probe needle 13 is electrically connected to the wiring 95d.

As a matter of course, another conductive body may be arranged in the gap between the wiring 95d and the probe needle 13. Another conductive body may be formed in a coil shape or a plate spring shape, for example. Also, the probe needle 13 may be attached directly to the card substrate 95. In this case, part of the probe needle 13 may be formed in a plate spring shape. The tester device 4 includes the tester main body 93 and the tester head 94 as well as the case of the second example embodiment described above.

In a case where the probe unit 7 of the vertical type is applied to the semiconductor structure 2C for inspection according to the second embodiment, the probe unit 7 includes at least two probe needles 13. Specifically, the at-least-two probe needles 13 include at least one probe needle 13 for gate to be abutted with the gate protective electrode 60a, and at least one probe needle 13 for source to be abutted with the source protective electrode 60b. As described above, even in a case where the probe unit 7 of the vertical type is adopted, the same effects as the effects exerted in each of the embodiments described above are exerted.

The embodiments described above can be further implemented in other modes. The embodiments described above show the example that the probe unit 7 is of the manipulator type, the cantilever type, or the vertical type. However, the mode of the probe unit 7 is not limited to particular modes but is arbitrary as long as the probe unit 7 has the probe needle 13.

Each of the embodiments described above shows the example that the semiconductor wafer 20 including SiC which serves as an example of the wide-bandgap semiconductor is adopted. However, a semiconductor wafer 20 including a wide-bandgap semiconductor other than SiC may be adopted. As the wide-bandgap semiconductor other than SiC, diamond, GaN (gallium nitride), etc., are exemplified.

Each of the embodiments described above shows the example that the insulating film 50 has the laminated structure including the inorganic insulating film 53 and the organic insulating film 54 laminated in this order from the first main surface electrode 40 side. However, the insulating film 50 may have a single layer structure including not the inorganic insulating film 53 but the organic insulating film 54.

Each of the embodiments described above shows the example that the protective electrode 60 (including the gate protective electrode 60a and the source protective electrode 60b) overlaps on the inner peripheral portion of the inorganic insulating film 53 and covers the organic insulating film 54. However, the protective electrode 60 (including the gate protective electrode 60a and the source protective electrode 60b) may overlap on the inner peripheral portion of the inorganic insulating film 53 at an interval from the organic insulating film 54 so as not to be in contact with the organic insulating film 54.

In this case, the Ni film 61 may overlap on the inner peripheral portion of the inorganic insulating film 53 at an interval from the organic insulating film 54 so as not to be in contact with the organic insulating film 54. Also, the Pd film 62 may have a part covering the Ni film 61 in a film shape and in contact with the inorganic insulating film 53. Also, the Au film 63 may have a part covering the Pd film 62 in a film shape and in contact with the inorganic insulating film 53. As a matter of course, an organic insulating film 54 covering the inner peripheral portion of the inorganic insulating film 53 may be formed, and a protective electrode 60 in contact only with the organic insulating film 54 may be formed in the pad opening 51 (including the gate pad opening 51a and the source pad opening 51b).

Each of the embodiments described above shows the example that the semiconductor structure 2A for inspection, the semiconductor structure 2B for manufacture, and the semiconductor structure 2C for inspection include the second main surface electrode 65. However, a semiconductor structure 2A for inspection, a semiconductor structure 2B for manufacture, and a semiconductor structure 2C for inspection including no second main surface electrode 65 may be adopted.

Each of the embodiments described above shows the example that the functional device 31 includes any one of the SBD and the MISFET. However, the functional device 31 may include both the SBD and the MISFET. That is, both the SBD and the MISFET may be formed in the same inspection region 30. As a matter of course, in each of the embodiments described above, the functional device 31 including the SBD and the functional device 31 including the MISFET may be formed in different inspection regions 30 in the same semiconductor wafer 20.

The second embodiment described above describes the example that the MISFET of the trench gate type serving as an example of the functional device 31 is formed. However, the functional device 31 may include a MISFET of a planar gate type in place of the trench gate type.

In the second embodiment described above, a p-type first semiconductor region 25 may be adopted in place of the n-type first semiconductor region 25. In this case, the functional device 31 includes an insulated gate bipolar transistor (IGBT) in place of the MISFET. A specific arrangement of this case can be obtained by replacing the “source” of the MISFET by an “emitter” of the IGBT and replacing the “drain” of the MISFET by a “collector” of the IGBT in the description above.

Each of the embodiments described above describes the mode that the first conductivity type is the n-type and the second conductivity type is the p-type. However, in each of the embodiments described above, a mode that the first conductivity type is the p-type and the second conductivity type is the n-type may be adopted. A specific arrangement of this case can be obtained by replacing the n-type region by the p-type region and replacing the p-type region by the n-type region in the description above and the attached drawings.

Hereinafter, examples of characteristics extracted from this specification and the drawings will be shown. Hereinafter, a highly reliable semiconductor structure for inspection is provided.

[A1] A semiconductor structure for inspection comprising: a semiconductor plate having a first main surface on one side and a second main surface on the other side; an inspection region provided in the first main surface; a main surface electrode having a first hardness and covering the first main surface in the inspection region; and a protective electrode having a second hardness which exceeds the first hardness, covering the main surface electrode in the inspection region, and forming a current path between the second main surface and the protective electrode via the semiconductor plate.

[A2] The semiconductor structure for inspection according to A1, wherein the inspection regions are provided in the first main surface, the main surface electrodes respectively cover the first main surface in the inspection regions, and the protective electrodes respectively cover the main surface electrodes in the inspection regions, and respectively form current paths between the second main surface and the protective electrodes.

[A3] The semiconductor structure for inspection according to A1 or A2, wherein the inspection regions are allocated in the first main surface along a first direction and a second direction crossing the first direction.

[A4] The semiconductor structure for inspection according to A2 or A3, wherein not less than one hundred inspection regions are provided in the first main surface.

[A5] The semiconductor structure for inspection according to any one of A1 to A4, wherein the semiconductor plate includes a wide-bandgap semiconductor.

[A6] The semiconductor structure for inspection according to any one of A1 to A5, wherein the semiconductor plate includes SiC.

[A7] The semiconductor structure for inspection according to any one of A1 to A6, wherein the protective electrode is formed as an object to be abutted with a probe needle, and has a thickness exceeding a depth of an abutment mark of the probe needle.

[A8] The semiconductor structure for inspection according to any one of A1 to A7, wherein the protective electrode has a thickness of not less than 0.05 μm.

[A9] The semiconductor structure for inspection according to any one of A1 to A8, wherein the protective electrode has a thickness of not more than 25 μm.

[A10] The semiconductor structure for inspection according to any one of A1 to A9, wherein the main surface electrode has a thickness of not less than 1 μm.

[A11] The semiconductor structure for inspection according to any one of A1 to A10, wherein the main surface electrode has a thickness of not more than 5.3 μm.

[A12] The semiconductor structure for inspection according to any one of A1 to A11, wherein the protective electrode is thicker than the main surface electrode.

[A13] The semiconductor structure for inspection according to any one of A1 to A12, wherein the main surface electrode consists of a metal film other than a plated film, and the protective electrode consists of a plated film.

[A14] The semiconductor structure for inspection according to any one of A1 to A13, wherein the main surface electrode includes an Al-based metal film, and the protective electrode includes an Ni film.

[A15] The semiconductor structure for inspection according to A14, wherein the Ni film is thicker than the Al-based metal film.

[A16] The semiconductor structure for inspection according to A14 or A15, wherein the Ni film has a thickness of not less than 0.03 μm and not more than 25 μm.

[A17] The semiconductor structure for inspection according to any one of A14 to A16, wherein the protective electrode includes an Au film laminated on the Ni film.

[A18] The semiconductor structure for inspection according to A17, wherein the Au film is thinner than the Ni film.

[A19] The semiconductor structure for inspection according to A17 or A18, wherein the Au film has a thickness of not less than 0.01 μm and not more than 0.2 μm.

[A20] The semiconductor structure for inspection according to any one of A17 to A19, wherein the protective electrode includes a Pd film interposed between the Ni film and the Au film.

[A21] The semiconductor structure for inspection according to A20, wherein the Pd film is thinner than the Ni film.

[A22] The semiconductor structure for inspection according to A20 or A21, wherein the Pd film has a thickness of not less than 0.01 μm and not more than 0.2 μm.

[A23] The semiconductor structure for inspection according to any one of A1 to A22, wherein the protective electrode has an area less than an area of the main surface electrode in a plan view.

[A24] The semiconductor structure for inspection according to any one of A1 to A23, further comprising: an insulating film covering a peripheral edge portion of the main surface electrode and having an opening from which an inner side portion of the main surface electrode is exposed, wherein the protective electrode covers the main surface electrode in the opening.

[A25] The semiconductor structure for inspection according to A24, wherein the protective electrode is thinner than the insulating film.

[A26] The semiconductor structure for inspection according to A25, wherein the protective electrode has an electrode surface placed on the main surface electrode side with respect to a surface of the insulating film.

[A27] The semiconductor structure for inspection according to any one of A24 to A26, wherein the protective electrode is formed at an interval from an opening end of the opening to the main surface electrode side so that part of a wall surface of the opening is exposed.

[A28] The semiconductor structure for inspection according to any one of A24 to A27, wherein the insulating film includes an organic film, and the protective electrode is in contact with the organic film in the opening.

[A29] The semiconductor structure for inspection according to A28, wherein the organic film has a thickness of not less than 5 μm and not more than 20 μm.

[A30] The semiconductor structure for inspection according to A28 or A29, wherein the protective electrode is thinner than the organic film.

[A31] The semiconductor structure for inspection according to any one of A28 to A30, wherein the organic film includes at least one of a polyimide film, a polyamide film, and a polybenzoxazole film.

[A32] The semiconductor structure for inspection according to any one of A28 to A31, wherein the insulating film includes an inorganic film interposed between the main surface electrode and the organic film.

[A33] The semiconductor structure for inspection according to A32, wherein the inorganic film has a thickness of not less than 0.5 μm and not more than 5 μm.

[A34] The semiconductor structure for inspection according to A32 or A33, wherein the protective electrode is thicker than the inorganic film.

[A35] The semiconductor structure for inspection according to any one of A32 to A34, wherein the inorganic film is exposed from the organic film in the opening, and the protective electrode is in contact with the inorganic film and the organic film in the opening.

[A36] The semiconductor structure for inspection according to any one of A1 to A35, further comprising: a functional device formed in the first main surface in the inspection region, wherein the main surface electrode is electrically connected to the functional device, and the protective electrode is electrically connected to the functional device via the main surface electrode and forms the current path between the second main surface and the protective electrode via the functional device.

[A37] The semiconductor structure for inspection according to A36, wherein the functional device includes at least one of a diode and a transistor.

[A38] The semiconductor structure for inspection according to any one of A1 to A37, further comprising: a second main surface electrode covering the second main surface and forming a current path between the protective electrode and the second main surface via the semiconductor plate.

[A39] The semiconductor structure for inspection according to A38, wherein the second main surface electrode covers the entire region of the second main surface.

[A40] A chuck stage inspection device comprising: a chuck stage having a conductive mounting surface; a conductive probe needle with an electric signal being given between the mounting surface and the probe needle; and the semiconductor structure for inspection according to any one of A1 to A39 to be arranged on the mounting surface in a posture that the second main surface is to be electrically connected to the mounting surface and the protective electrode is to be abutted with the probe needle.

[A41] The chuck stage inspection device according to A40, wherein the probe needle is arranged so that an electric current is given between the mounting surface and the probe needle.

[A42] A chuck stage inspection device comprising: a prober device including a chuck stage which has a conductive mounting surface and a conductive probe needle; a tester device electrically connected to the mounting surface and the probe needle, the tester device that gives an electric signal between the mounting surface and the probe needle; and the semiconductor structure for inspection according to any one of A1 to A39 to be arranged on the mounting surface in a posture that the second main surface is to be electrically connected to the mounting surface and the protective electrode is to be abutted with the probe needle.

[A43] The chuck stage inspection device according to A42, wherein the tester device is configured to acquire at least one of a voltage value and a resistance value between the probe needle and the chuck stage.

[A44] An inspecting method of a chuck stage by using a semiconductor evaluation device including a chuck stage which has a conductive mounting surface and a conductive probe needle with an electric signal being given between the mounting surface and the probe needle, the inspecting method comprising: a step of arranging the semiconductor structure for inspection according to any one of A1 to A39 on the mounting surface in a posture that the second main surface is to be electrically connected to the mounting surface; and a step of abutting the probe needle with the protective electrode, giving an electric signal between the mounting surface and the probe needle via the semiconductor structure for inspection, and inspecting a state of the mounting surface from an energization result of the mounting surface and the probe needle.

[A45] An inspecting method of a chuck stage by using a semiconductor evaluation device including a prober device which includes a chuck stage having a conductive mounting surface and a conductive probe needle, and a tester device electrically connected to the mounting surface and the probe needle, the tester device that gives an electric signal between the mounting surface and the probe needle, the inspecting method comprising: a step of arranging the semiconductor structure for inspection according to any one of A1 to A39 on the mounting surface in a posture that the second main surface is to be electrically connected to the mounting surface; and a step of abutting the probe needle with the protective electrode, giving an electric signal between the mounting surface and the probe needle via the semiconductor structure for inspection, and inspecting a state of the mounting surface from an energization result of the mounting surface and the probe needle.

[A46] A manufacturing method of a semiconductor device comprising: a step of arranging a semiconductor structure for manufacture to be processed into the semiconductor device on the mounting surface so as to be electrically connected to the mounting surface after implementing the inspecting method of the chuck stage according to A44 or A45; and a step of abutting the probe needle with the semiconductor structure for manufacture, giving an electric signal between the mounting surface and the probe needle via the semiconductor structure for manufacture, and inspecting electrical characteristics of the semiconductor structure for manufacture.

[A47] A manufacturing method of a semiconductor device by using a semiconductor evaluation device including a chuck stage which has a conductive mounting surface and a conductive probe needle with an electric signal being given between the mounting surface and the probe needle, the manufacturing method comprising: a step of arranging the semiconductor structure for inspection according to any one of A1 to A39 on the mounting surface in a posture that the second main surface is to be electrically connected to the mounting surface; and a step of abutting the probe needle with the protective electrode, giving an electric signal between the mounting surface and the probe needle via the semiconductor structure for inspection, and inspecting a state of the mounting surface from an energization result of the mounting surface and the probe needle.

[A48] A manufacturing method of a semiconductor device by using a semiconductor evaluation device including a prober device which includes a chuck stage having a conductive mounting surface and a conductive probe needle, and a tester device electrically connected to the mounting surface and the probe needle, the tester device that gives an electric signal between the mounting surface and the probe needle, the manufacturing method comprising: a step of arranging the semiconductor structure for inspection according to any one of A1 to A39 on the mounting surface in a posture that the second main surface is to be electrically connected to the mounting surface; and a step of abutting the probe needle with the protective electrode, giving an electric signal between the mounting surface and the probe needle via the semiconductor structure for inspection, and inspecting a state of the mounting surface from an energization result of the mounting surface and the probe needle.

Although the embodiments have been described in detail, these embodiments are merely concrete examples used to clarify the technical contents, and the present invention should not be interpreted by being limited to these specific examples, and the scope of the present invention is limited by the appended claims.

What is claimed is:

1. A semiconductor structure for inspection comprising:
a semiconductor plate having a first main surface on one side and a second main surface on the other side;
an inspection region provided in the first main surface;
a main surface electrode having a first hardness and covering the first main surface in the inspection region; and
a protective electrode having a second hardness which exceeds the first hardness, covering the main surface electrode in the inspection region, and forming a current path between the second main surface and the protective electrode via the semiconductor plate.

2. The semiconductor structure for inspection according to claim 1,
wherein the inspection regions are provided in the first main surface,
the main surface electrodes respectively cover the first main surface in the inspection regions, and
the protective electrodes respectively cover the main surface electrodes in the inspection regions, and respectively form the current paths between the second main surface and the protective electrodes.

3. The semiconductor structure for inspection according to claim 1,
wherein the inspection regions are allocated in the first main surface along a first direction and a second direction crossing the first direction.

4. The semiconductor structure for inspection according to claim 2,
wherein not less than one hundred inspection regions are provided in the first main surface.

5. The semiconductor structure for inspection according to claim 1,
wherein the semiconductor plate includes a wide-bandgap semiconductor.

6. The semiconductor structure for inspection according to claim 1,
wherein the semiconductor plate includes SiC.

7. The semiconductor structure for inspection according to claim 1,
wherein the protective electrode is formed as an object to be abutted with a probe needle, and has a thickness exceeding a depth of an abutment mark of the probe needle.

8. The semiconductor structure for inspection according to claim 1,
wherein the main surface electrode consists of a metal film other than a plated film, and
the protective electrode consists of a plated film.

9. The semiconductor structure for inspection according to claim 1,
wherein the main surface electrode includes an Al-based metal film, and
the protective electrode includes an Ni film.

10. The semiconductor structure for inspection according to claim 9,
wherein the protective electrode has a laminated structure including an Au film laminated on the Ni film.

11. The semiconductor structure for inspection according to claim 10,
wherein the protective electrode includes a Pd film interposed between the Ni film and the Au film.

12. The semiconductor structure for inspection according to claim 1,
wherein the protective electrode has an area less than an area of the main surface electrode in a plan view.

13. The semiconductor structure for inspection according to claim 1, further comprising:
an insulating film covering a peripheral edge portion of the main surface electrode and having an opening from which an inner side portion of the main surface electrode is exposed;
wherein the protective electrode covers the main surface electrode in the opening.

14. The semiconductor structure for inspection according to claim 13,
wherein the protective electrode is formed at an interval from an opening end of the opening to the main surface electrode side so that part of a wall surface of the opening is exposed.

15. The semiconductor structure for inspection according to claim 1, further comprising:
a functional device formed in the first main surface in the inspection region;
wherein the main surface electrode is electrically connected to the functional device, and
the protective electrode is electrically connected to the functional device via the main surface electrode and forms the current path between the second main surface and the protective electrode via the functional device.

16. The semiconductor structure for inspection according to claim 15,
wherein the functional device includes at least one of a diode and a transistor.

17. The semiconductor structure for inspection according to claim 1, further comprising:
a second main surface electrode covering the second main surface and forming a current path between the protective electrode and the second main surface via the semiconductor plate.

18. A chuck stage inspection device comprising:
a chuck stage having a conductive mounting surface;
a conductive probe needle with an electric signal being given between the mounting surface and the probe needle; and
the semiconductor structure for inspection according to claim 1 to be arranged on the mounting surface in a posture that the second main surface is to be electrically connected to the mounting surface and the protective electrode is to be abutted with the probe needle.

19. The chuck stage inspection device according to claim 18,
wherein the probe needle is arranged so that an electric current is given between the mounting surface and the probe needle.

20. A manufacturing method of a semiconductor device by using a semiconductor evaluation device including a chuck stage which has a conductive mounting surface and a conductive probe needle with an electric signal being given between the mounting surface and the probe needle, the manufacturing method comprising:
a step of arranging the semiconductor structure for inspection according to claim 1 on the mounting surface in a posture that the second main surface is to be electrically connected to the mounting surface; and
a step of abutting the probe needle with the protective electrode, giving an electric signal between the mounting surface and the probe needle via the semiconductor structure for inspection, and inspecting a state of the mounting surface from an energization result of the mounting surface and the probe needle.
